(19) United States
(12) Patent Application Publication
(10) Pub. No.: US 2025/0096527 A1
(43) Pub. Date: Mar. 20, 2025

(54) SURFACE EMITTING LASER, SURFACE EMITTING LASER ARRAY, AND LIGHT SOURCE DEVICE

(71) Applicant: SONY GROUP CORPORATION, Tokyo (JP)

(72) Inventors: Shuhei YAMAGUCHI, Kanagawa (JP); Gyongsok SONG, Kanagawa (JP); Hideki WATANABE, Kanagawa (JP); Rintaro KODA, Tokyo (JP); Yasutaka HIGA, Tokyo (JP); Tatsuya MATOU, Kanagawa (JP)

(21) Appl. No.: 18/729,311

(22) PCT Filed: Dec. 12, 2022
(86) PCT No.: PCT/JP2022/045672

§ 371 Date: Jul. 16, 2024

(30) Foreign Application Priority Data
Feb. 1, 2022 (JP) 2022-014158

(51) Int. Cl. H01S 5/042; H01S 5/183; H01S 5/42

(52) U.S. Cl. CPC H01S 5/04256; H01S 5/04253; H01S 5/18361; H01S 5/423; H01S 5/18305

(57) ABSTRACT

Provided is a surface emitting laser capable of increasing the size of a light emitting portion while curbing an increase in size as a whole.

A surface emitting laser according to the present technology includes: a first structure that includes a first multilayer reflector; a second structure that includes a second multilayer reflector; an active layer that is disposed between the first and second structures; a first electrode that is electrically connected to the first structure; and a second electrode that is electrically connected to the second structure, and the first and second electrodes are provided in the second structure in a state where the first and second electrodes are insulated from each other. According to the surface emitting laser of the present technology, it is possible to provide a surface emitting laser capable of increasing the size of a light emitting portion while curbing an increase in size as a whole.

### TECHNICAL FIELD

A technology according to the present disclosure (hereinafter, also referred to as a “present technology”) relates to a surface emitting laser, a surface emitting laser array, and a light source device.

### BACKGROUND ART

In the related art, a surface emitting laser with an anode electrode and a cathode electrode for injecting a current into an active layer provided on the same surface side is known (see PTL 1 and 2).

### CITATION LIST

### Patent Literature

[PTL 1]
JP 2003-23211A
[PTL 2]
JP 2002-368334A

### SUMMARY

### Technical Problem

However, there is room for improvement in the surface emitting laser in the related art in regard to increasing the size of a light emitting portion while curbing an increase in size as a whole.

Thus, an object of the present technology is to provide a surface emitting laser capable of increasing the size of a light emitting portion while curbing an increase in size as a whole.

### Solution to Problem

The present technology provides a surface emitting laser including:
a first structure that includes a first multilayer reflector;
a second structure that includes a second multilayer reflector;
an active layer that is disposed between the first and second structures;
a first electrode that is electrically connected to the first structure; and
a second electrode that is electrically connected to the second structure, in which
the first and second electrodes are provided in the second structure in a state where the first and second electrodes are insulated from each other.

The first and second electrodes may be disposed in the second structure on a side opposite to a side of the active layer.

The first and second electrodes may be disposed to be aligned in at least one of a stacked direction and an in-plane direction.

The second electrode may be provided on a surface of the second structure on the side opposite to the side of the active layer.

The first and second electrodes may be stacked via an insulating film.

The first electrode may be provided on the surface via an insulating film.

The first electrode may be smaller than the second electrode.

One of the first and second electrodes may surround the other in a plan view.

The first electrode may be another portion of a wiring, a portion of which is connected to the first structure.

A mesa having a top portion in the second structure may be configured by at least the second structure and the active layer from among a portion of the first structure, the second structure, and the active layer, and the wiring may be provided along the mesa via an insulating film.

The portion of the wiring may be in contact with a surface of the first structure exposed in surroundings of the mesa.

The first structure may further include a substrate that is disposed on the side opposite to the side of the active layer with respect to the first multilayer reflector and a contact layer that is disposed between the substrate and the active layer and is exposed in the surroundings of the mesa, and the portion of the wiring may be in contact with the contact layer.

The first structure may further include a cladding layer that is disposed on the first multilayer reflector on the side of the active layer and is exposed in the surroundings of the mesa, and the portion of the wiring may be in contact with the cladding layer.

A plurality of the first electrodes may be provided.

The wiring may be provided to penetrate through at least the second structure and the active layer from among the first structure, the second structure, and the active layer and may be surrounded by an insulating region that is provided across at least the second structure and the active layer from among the first structure, the second structure, and the active layer.

The first structure may further include a substrate that is disposed on a side opposite to a side of the active layer with respect to the first multilayer reflector and a contact layer that is disposed between the substrate and the active layer, and the portion of the wiring may be in contact with the contact layer.

At least the second electrode out of the first and second electrodes may be made of a transparent conductive film.

The present technology also provides a surface emitting laser array including a plurality of the surface emitting lasers.

The first electrode and/or the second electrode may be provided commonly in at least two of the surface emitting lasers.

The present technology also provides a light source device including: the surface emitting laser; and a laser driver that is electrically connected to each of the first and second electrodes of the surface emitting laser via a conductive bump.

The first electrode may include an opening portion, the insulating film may include a first opening portion that is provided at a position corresponding to the opening portion and is smaller than the opening portion, and the first electrode may be covered with a different insulating film including a second opening portion that is provided at a position corresponding to the opening portion and is smaller than the opening portion.

The second electrode may be provided to penetrate through the first and second opening portions.

The second electrode may include a first part that is present between the surface and the insulating film, a second part that is present inside the first and second opening portions, and a third part that is present at least on the second part.

The third part may also be present on a region in surroundings of the second opening portion in the different insulating film.

A plurality of the surface emitting lasers may be included, and the first electrodes of the plurality of surface emitting lasers may be electrically connected.

### BRIEF DESCRIPTION OF DRAWINGS

FIG. 1 is a sectional view of a surface emitting laser according to a first example of a first embodiment of the present technology.

FIG. 2 is a plan view of the surface emitting laser according to the first example of the first embodiment of the present technology.

FIG. 3 is a flowchart for explaining a method for manufacturing the surface emitting laser in FIG. 1.

FIGS. 4A and 4B are sectional views for each process of the method for manufacturing the surface emitting laser in FIG. 1.

FIGS. 5A and 5B are sectional views for each process of the method for manufacturing the surface emitting laser in FIG. 1.

FIGS. 6A and 6B are sectional views for each process of the method for manufacturing the surface emitting laser in FIG. 1.

FIGS. 7A and 7B are sectional views for each process of the method for manufacturing the surface emitting laser in FIG. 1.

FIGS. 8A and 8B are sectional views for each process of the method for manufacturing the surface emitting laser in FIG. 1.

FIGS. 9A and 9B are sectional views for each process of the method for manufacturing the surface emitting laser in FIG. 1.

FIG. 10 is a sectional view for each process of the method for manufacturing the surface emitting laser in FIG. 1.

FIG. 11 is a sectional view of a surface emitting laser according to a second example of the first embodiment of the present technology.

FIG. 12 is a plan view of a surface emitting laser according to a third example of the first embodiment of the present technology.

FIG. 13 is a sectional view of a surface emitting laser according to a fourth example of the first embodiment of the present technology.

FIG. 14 is a sectional view of a surface emitting laser according to a fifth example of the first embodiment of the present technology.

FIG. 15 is a plan view of a surface emitting laser according to a fifth example of the first embodiment of the present technology.

FIG. 16 is a sectional view of a surface emitting laser according to a sixth example of the first embodiment of the present technology.

FIG. 17 is a flowchart for explaining a method for manufacturing the surface emitting laser in FIG. 16.

FIGS. 18A and 18B are sectional views for each process of the method for manufacturing the surface emitting laser in FIG. 16.

FIGS. 19A and 19B are sectional views for each process of the method for manufacturing the surface emitting laser in FIG. 16.

FIG. 20 is a sectional view for each process of the method for manufacturing the surface emitting laser in FIG. 16.

FIG. 21 is a sectional view for each process of the method for manufacturing the surface emitting laser in FIG. 16.

FIGS. 22A and 22B are sectional views for each process of the method for manufacturing the surface emitting laser in FIG. 16.

FIGS. 23A and 23B are sectional views for each process of the method for manufacturing the surface emitting laser in FIG. 16.

FIG. 24 is a sectional view of a surface emitting laser array according to a seventh example of the first embodiment of the present technology.

FIG. 25 is a plan view of the surface emitting laser array according to the seventh example of the first embodiment of the present technology.

FIG. 26 is a flowchart for explaining a method for manufacturing the surface emitting laser array in FIG. 24.

FIGS. 27A and 27B are sectional views for each process of the method for manufacturing the surface emitting laser array in FIG. 24.

FIGS. 28A and 28B are sectional views for each process of the method for manufacturing the surface emitting laser array in FIG. 24.

FIGS. 29A and 29B are sectional views for each process of the method for manufacturing the surface emitting laser array in FIG. 24.

FIGS. 30A to 30C are sectional views for each process of the method for manufacturing the surface emitting laser array in FIG. 24.

FIGS. 31A and 31B are sectional views for each process of the method for manufacturing the surface emitting laser array in FIG. 24.

FIG. 32 is a sectional view of a surface emitting laser according to an eighth example of the first embodiment of the present technology.

FIG. 33 is a plan view of a surface emitting laser according to an eighth example of the first embodiment of the present technology.

FIG. 34 is a flowchart for explaining a method for manufacturing the surface emitting laser in FIG. 32.

FIGS. 35A and 35B are sectional views for each process of the method for manufacturing the surface emitting laser in FIG. 32.

FIGS. 36A and 36B are sectional views for each process of the method for manufacturing the surface emitting laser in FIG. 32.

FIGS. 37A and 37B are sectional views for each process of the method for manufacturing the surface emitting laser in FIG. 32.

FIG. 38 is a sectional view illustrating a state before bonding of a light source device according to a first example of a second embodiment of the present technology.

FIG. 39 is a plan view of a surface emitting laser of the light source device in FIG. 38.

FIG. 40 is a sectional view illustrating a state before bonding of a light source device according to a modification of the first example of the second embodiment of the present technology.

FIG. 41 is a sectional view illustrating a state before bonding of a light source device according to a second example of the second embodiment of the present technology.

FIG. 42 is a plan view of a surface emitting laser of the light source device in FIG. 41.

FIG. 43 is a sectional view illustrating a state before bonding of a light source device according to a modification of the second example of the second embodiment of the present technology.

FIG. 44 is a sectional view illustrating a state before bonding of a light source device according to a third example of the second embodiment of the present technology.

FIG. 45 is a plan view of a surface emitting laser array of the light source device in FIG. 44.

FIG. 46 is a sectional view illustrating a state before bonding of a light source device according to a modification of the third example of the second embodiment of the present technology.

FIG. 47 is a sectional view of a surface emitting laser according to a modification of the fourth example of the first embodiment of the present technology.

FIG. 48 is a sectional view of a surface emitting laser array according to a first modification of the seventh example of the first embodiment of the present technology.

FIG. 49 is a flowchart for explaining a method for manufacturing the surface emitting laser array in FIG. 48.

FIGS. 50A and 50B are sectional views for each process of the method for manufacturing the surface emitting laser array in FIG. 48.

FIGS. 51A and 51B are sectional views for each process of the method for manufacturing the surface emitting laser array in FIG. 48.

FIGS. 52A to 52C are sectional views for each process of the method for manufacturing the surface emitting laser array in FIG. 48.

FIGS. 53A to 53C are sectional views for each process of the method for manufacturing the surface emitting laser array in FIG. 48.

FIG. 54 is a sectional view of a surface emitting laser according to a second modification of the seventh example of the first embodiment of the present technology.

FIG. 55 is a sectional view of a surface emitting laser according to a third modification of the seventh example of the first embodiment of the present technology.

FIG. 56 is a sectional view of a surface emitting laser according to a ninth example of the first embodiment of the present technology.

FIG. 57 is a sectional view of a surface emitting laser array according to a tenth example of the first embodiment of the present technology.

FIG. 58 is a diagram illustrating an example of an application of the surface emitting laser according to the first example of the first embodiment of the present technology to a distance measurement distance.

FIG. 59 is a block diagram illustrating an example of a schematic configuration of a vehicle control system.

FIG. 60 is an explanatory diagram illustrating an example of an installation position of the distance measurement device.

### DESCRIPTION OF EMBODIMENTS

Preferred embodiments of the present technology will be described in detail with reference to the accompanying figures below. In the present specification and the drawings, components having substantially the same functional configuration will be denoted by the same reference numerals, and thus repeated descriptions thereof will be omitted. The embodiments to be described below show a representative embodiment of the present technology, and the scope of the present technology should not be narrowly instructed based on this. It is only necessary for the surface emitting laser, the surface emitting laser array, and the light source according to the present technology to exhibit at least one effect even in a case where there is description that the surface emitting laser, the surface emitting laser array, and the light source device according to the present technology exhibit a plurality of effects in the specification. The advantageous effects described in the present specification are merely exemplary and are not limited, and other advantageous effects may be obtained.

The description will be made in the following order.

### 0. Introduction

1. Surface emitting laser according to first example of first embodiment of present technology
2. Surface emitting laser according to second example of first embodiment of present technology
3. Surface emitting laser according to third example of first embodiment of present technology
4. Surface emitting laser according to fourth example of first embodiment of present technology
5. Surface emitting laser according to fifth example of first embodiment of present technology
6. Surface emitting laser according to sixth example of first embodiment of present technology
7. Surface emitting laser array according to seventh example of first embodiment of present technology
8. Surface emitting laser according to eighth example of first embodiment of present technology
9. Light source device according to first example of second embodiment of present technology
10. Light source device according to modification of first example of second embodiment of present technology
11. Light source device according to second example of second embodiment of present technology
12. Light source device according to modification of second example of second embodiment of present technology
13. Light source device according to third example of second embodiment of present technology
14. Light source device according to modification of third example of second embodiment of present technology
15. Surface emitting laser according to modification of fourth example of first embodiment of present technology
16. Surface emitting laser array according to first modification of seventh example of first embodiment of present technology
17. Surface emitting laser according to second modification of seventh example of first embodiment of present technology
18. Surface emitting laser according to third modification of seventh example of first embodiment of present technology
19. Surface emitting laser according to ninth example of first embodiment of present technology
20. Surface emitting laser array according to tenth example of first embodiment of present technology
21. Examples of other modifications of present technology
22. Example of applications to electronic devices
23. Example in which surface emitting laser is applied to distance measurement device
24. Example in which distance measurement device is mounted in mobile object

### <0. Introduction>

In a case where an anode electrode and a cathode electrode are provided on the same surface side in a typical vertical cavity surface emitting laser (VCSEL), one of the anode electrode and the cathode electrode is disposed on a light emitting portion, and the other is disposed in the surroundings of the light emitting portion. In this case, it is necessary to secure a wiring connection region in the surroundings of the light emitting portion, and there is thus a problem that an increase in size of the light emitting portion may lead to an increase in size as a whole.

Thus, the present inventors developed a surface emitting laser according to the present technology as a surface emitting laser capable of increasing the size of a light emitting portion while curbing an increase in size as a whole as a result of intensive studies.

Hereinafter, a surface emitting laser or a surface emitting laser array according to a first embodiment of the present technology will be described in detail by exemplifying some examples.

### <1. Surface Emitting Laser According to First Example of First Embodiment of Present Technology>

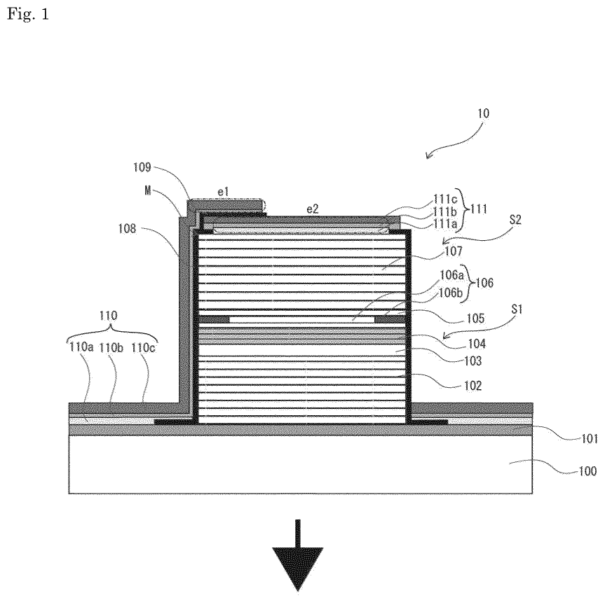

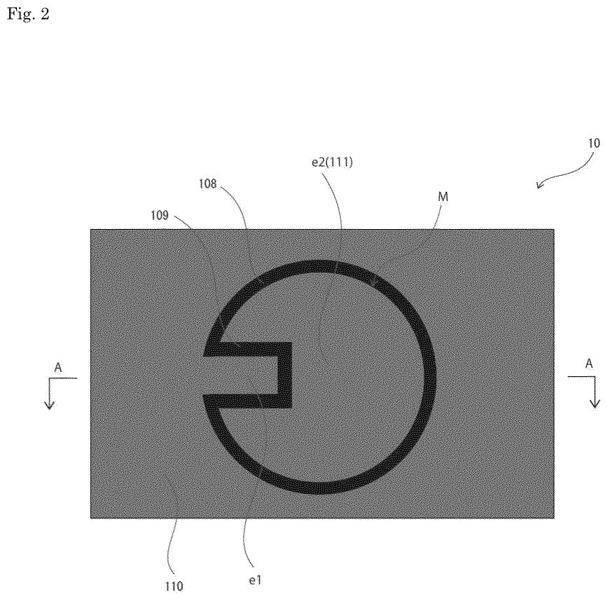

FIG. 1 is a sectional view of a surface emitting laser 10 according to a first example of the first embodiment of the present technology. FIG. 2 is a plan view of the surface emitting laser in FIG. 1. FIG. 1 is a sectional view along the line A-A in FIG. 2. The following description will be given on the assumption that the upper side in the sectional views such as FIG. 1 and the like is an upper side and the lower side therein is a lower side for convenience.

### <<Configuration of Surface Emitting Laser>>

### (Overall Configuration)

The surface emitting laser 10 according to the first example is a vertical cavity surface emitting laser (VCSEL). The surface emitting laser 10 includes a first structure S1 that includes a first multilayer reflector 102, a second structure S2 that includes a second multilayer reflector 107, an active layer 104 that is disposed between the first and second structures S1 and S2, a first electrode e1 that is electrically connected to the first structure S1, and a second electrode e2 that is electrically connected to the second structure S2 as illustrated in FIG. 1. The surface emitting laser 10 is driven by a laser driver, for example.

The first structure S1 includes a substrate 100 that is disposed on a side opposite to the side of the active layer 104 with respect to the first multilayer reflector 102, a contact layer 101 that is disposed between the substrate 100 and the first multilayer reflector 102, and a first cladding layer 103 that is disposed between the first multilayer reflector 102 and the active layer 104.

The second structure S2 further includes a second cladding layer 105 that is disposed between the second multilayer reflector 107 and the active layer 104. An oxidation constriction layer 106 is provided inside the second cladding layer 105.

A light emitting portion (resonator) is configured to include the first and second structures S1 and S2 and the active layer 104.

A mesa M having a top portion in the second structure S2 is configured by a portion of the first structure S1, the second structure S2, and the active layer 104. The mesa M configures at least a portion of the light emitting portion. The mesa M is configured to include the first multilayer reflector 102, the first cladding layer 103, the active layer 104, the second cladding layer 105 including the oxidation constriction layer 106, and the second multilayer reflector 107 in an example. Although the mesa M has a substantially cylindrical shape, for example, the mesa M may have another shape such as a substantially elliptical cylinder shape, a polygonal prism shape, a truncated cone shape, an elliptical truncated cone shape, or a polygonal truncated prism shape. A height direction of the mesa M substantially coincides with a stacked direction (up-down direction) of the surface emitting laser 10. The diameter of the mesa M is, for example, 1 μm to 500 μm.

The surface emitting laser 10 emits laser light from the side of a rear surface (lower surface) of the substrate 100 in an example. In other words, the surface emitting laser 10 is a VCSEL of a rear surface emitting type in an example.

### (Substrate)

The substrate 100 is made of a semiconductor substrate (a GaAs substrate, for example) of a first conductivity type (an n type, for example) in an example. A thin film that does not or substantially does not absorb light emitted by the surface emitting laser 10 (light with an oscillation wavelength A from the surface emitting laser 10) is formed as an AR coating film on the rear surface (lower surface) of the substrate 100.

### (Contact Layer)

The contact layer 101 is made of a semiconductor layer (a GaAs layer, for example) of a first conductivity type (an n type, for example) in an example. The contact layer 101 has a higher doping concentration of impurities and a lower resistance than the substrate 100.

### (First Multilayer Reflector)

The first multilayer reflector 102 is a semiconductor multilayer reflector in an example. The multilayer reflector is also called a distributed Bragg reflector. The semiconductor multilayer reflector that is one kind of multilayer reflector (distributed Bragg reflector) has low light absorption and high reflectance and conductivity. Specifically, the first multilayer reflector 102 is a semiconductor multilayer reflector of a first conductivity type (an n type, for example) and has a structure in which a plurality of kinds (two kinds, for example) of semiconductor layers with mutually different refractive indexes are alternately stacked with an optical thickness of a wavelength that is ¼ the oscillation wavelength in an example. Each refractive index layer of the first multilayer reflector 102 is made of an AlGaAs-based compound semiconductor of the first conductivity type (the n type, for example). The reflectance of the first multilayer reflector 102 is set to be slightly lower than that of the second multilayer reflector 107.

### (First Cladding Layer)

The first cladding layer 103 is made of an AlGaAs-based compound semiconductor of the first conductivity type (the n type, for example) in an example.

### (Active Layer)

The active layer 104 has a quantum well structure including a barrier layer made of an AlGaAs-based compound semiconductor and a quantum well layer in an example. The quantum well structure may be a single-quantum well structure (QW structure) or may be a multiquantum well structure (MQW structure). A region of the active layer 104 corresponding to a non-oxidation region 106a (current passing portion) of the oxidation constriction layer 106, which will be described later, is a light emitting region. Note that the active layer 104 may have a plurality of QW structures or a plurality of MQW structures that are stacked via tunnel junctions.

### (Second Cladding Layer)

The second cladding layer 105 is made of an AlGaAs-based compound semiconductor of a second conductivity type (a p type, for example) in an example.

### (Oxidation Constriction Layer)

The oxidation constriction layer 106 includes the non-oxidation region 106a made of AlAs and an oxidation region 106b made of an oxide of AlAs (Al₂O₃, for example) surrounding the periphery thereof. The non-oxidation region 106a functions as a current and light passing portion, while the oxidation region 106b functions as a current and light confinement portion.

### (Second Multilayer Reflector)

The second multilayer reflector 107 is a semiconductor multilayer reflector in an example. Specifically, the second multilayer reflector 107 is a semiconductor multilayer reflector of the second conductivity type (the p type, for example) and has a structure in which a plurality of kinds (two kinds, for example) of semiconductor layers with mutually different refractive indexes are alternately stacked with an optical thickness of a wavelength that is ¼ the oscillation wavelength in an example. Each refractive index layer of the second multilayer reflector 107 is made of an AlGaAs-based compound semiconductor of the second conductivity type (the p type, for example).

### (First and Second Electrodes)

The first and second electrodes e1 and e2 are provided in the second structure S2 in a state where they are insulated from each other. In FIG. 1, the first electrode e1 is a region surrounded by the one-dotted dashed line, and the second electrode e2 is a region surrounded by the two-dotted dashed line (the same applies to other drawings). The first electrode e1 functions as a cathode electrode and is electrically connected to a negative electrode (negative pole) of a laser driver, for example. The second electrode e2 functions as an anode electrode and is electrically connected to a positive electrode (positive pole) of the laser driver, for example.

The first and second electrodes e1 and e2 are disposed on the second structure S2 on the side (upper side) opposite to the side (lower side) of the active layer 104 in an example. Specifically, the first and second electrodes e1 and e2 are disposed to be aligned in the stacked direction (up-down direction) on the second structure S2 in an example.

The second electrode e2 is provided on the surface of the second structure S2 (specifically, on the upper surface of the second multilayer reflector 107) on the side opposite to the side of the active layer 104 in an example. The first and second electrodes e1 and e2 are stacked via an insulating film 109. Specifically, the first electrode e1 is disposed on the second electrode e2 via the insulating film 109.

The first electrode e1 is smaller than the second electrode e2 in an example (see FIG. 2). In an example, the second electrode e2 is provided in the entire region except for an outer edge portion of the top portion of the mesa M, and the first electrode e1 is provided at one end portion of the top portion of the mesa M. In an example, the second electrode e2 has a substantially circular shape in a plan view, and the first electrode e1 has a substantially rectangular shape in a plan view. A region where the first electrode e1 and the second electrode e2 are exposed serves as a connection region for flip-chip connection to the laser driver, for example.

The first electrode e1 is another portion (an end portion, for example) of a wiring 110, a portion of which is connected to the first structure S1. The wiring 110 is provided along the mesa M via the insulating films 108 and 109. In other words, the wiring 110 is insulated from the second structure S2. A portion of the wiring 110 is in contact with the surface of the first structure S1 exposed in the surroundings of the mesa M (specifically, the surface of the contact layer 101 exposed in the surroundings of the mesa M).

### (Wiring)

The wiring 110 has a stacked structure (a three-layer structure, for example) in which a first contact metal 110a, a first pad metal 110b, and a first plated metal 110c are stacked in this order in an example.

The first contact metal 110a is provided to be in contact with the surface of the contact layer 101 exposed in the surroundings of the mesa M. The first contact metal 110a has a stacked structure (a three-layer structure, for example) in which an AuGe layer, an Ni layer, and an Au layer are stacked in this order from the side of the contact layer 101, for example. The thickness of the AuGe layer is, for example, 2 nm to 300 nm. The thickness of the Ni layer is, for example, 2 nm to 300 nm. The thickness of the Au layer is, for example, 100 nm to 500 nm.

The first pad metal 110b has a stacked structure (a three-layer structure, for example) in which a Ti layer, a Pt layer, and an Au layer are stacked in this order from the side of the first contact metal 110a and the side of the mesa M, for example. The thickness of the Ti layer is, for example, 2 nm to 100 nm. The thickness of the Pt layer is, for example, 2 nm to 300 nm. The thickness of the Au layer is, for example, 100 nm to 1000 nm.

The first plated metal 110c is configured of an Au layer, for example. The thickness of the Au layer is, for example, 1000 nm to 5000 nm. The first plated metal 110c may not be provided as long as it is possible to prevent rupture of the first pad metal 110b by forming the first pad metal 110b to be thick, for example, and it is possible to reduce the resistance.

### (Insulating Films)

The insulating films 108 and 109 are made of a dielectric substance such as SiO₂, SiN, or SiON, for example. The film thickness of each insulating film is, for example, 10 to 300 nm.

### (Second Electrode)

The second electrode e2 is at least a portion (the entirety, for example) in an in-plane direction of a stacked electrode 111 with a stacked structure (a three-layer structure, for example) in which a second contact metal 111a, a second pad metal 111b, and a second plated metal 111c are stacked in this order in an example.

The second contact metal 111a is provided to be in contact with the surface (upper surface) of the second multilayer reflector 107 on the side opposite to the side of the active layer 104 in an example. The second contact metal 111a has a stacked structure (a three-layer structure) in which a Ti layer, a Pt layer, and an Au layer are stacked in this order from the side of the second multilayer reflector 107, for example. The thickness of the Ti layer is, for example, 2 nm to 100 nm. The thickness of the Pt layer is, for example, 2 nm to 300 nm. The thickness of the Au layer is, for example, 100 nm to 500 nm.

The second pad metal 111b has a stacked structure (a three-layer structure, for example) in which a Ti layer, a Pt layer, and an Au layer are stacked in this order from the side of the second contact metal 111a, for example. The thickness of the Ti layer is, for example, 2 nm to 100 nm. The thickness of the Pt layer is, for example, 2 nm to 300 nm. The thickness of the Au layer is, for example, 100 nm to 1000 nm.

The second plated metal 111c is configured of an Au layer, for example. The thickness of the Au layer is, for example, 1000 nm to 5000 nm. The second plated metal 111c may not be provided as long as it is possible to prevent rupture of the second pad metal 111b by forming the second pad metal 111b to be thick, for example, and it is possible to reduce the resistance.

### <<Operations of Surface Emitting Laser>>

In the surface emitting laser 10, a current that has been supplied from the side of the positive electrode of the laser driver, for example, and has flowed in from the second electrode e2 (anode electrode) is constricted by the oxidation constriction layer 106 via the second multilayer reflector 107 and is then injected to the active layer 104. At this time, the active layer 104 emits light, the light reciprocates between the first and second multilayer reflectors 102 and 107 while being amplified by the active layer 104 and confined by the oxidation constriction layer 106, and when an oscillation condition is satisfied, the light is emitted as laser light from the rear surface of the substrate 100. The current that has passed through the active layer 104 reaches the first electrode e1 (cathode electrode) via the first cladding layer 103, the first multilayer reflector 102, and the contact layer 101 and is caused to flow out from the first electrode e1 to the side of the negative electrode of the laser driver, for example.

### <<Method for Manufacturing Surface Emitting Laser>>

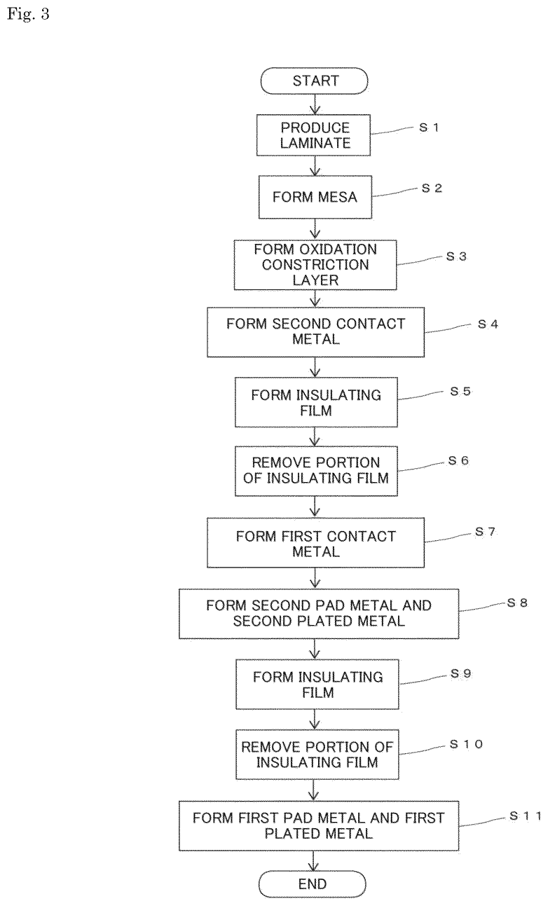

Hereinafter, a method for manufacturing the surface emitting laser 10 will be described with reference to the flowchart (Steps S1 to S11) in FIG. 3. Here, a plurality of surface emitting lasers 10 are simultaneously produced on a single wafer that is a base material of the substrate 100 by a semiconductor manufacturing method using a semiconductor manufacturing device in an example. Then, the series of plurality of integrated surface emitting lasers 10 are separated from each other to thereby obtain a plurality of surface emitting lasers 10 with a chip shape.

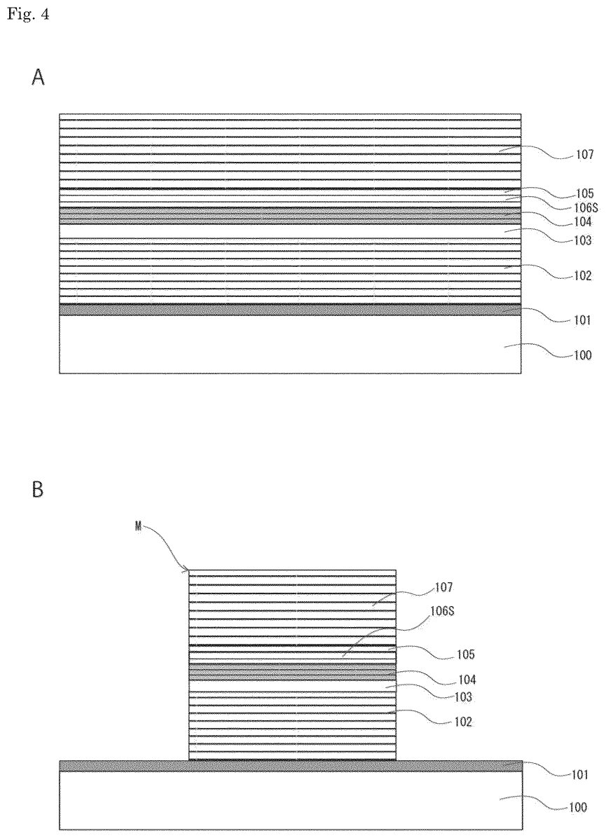

In first Step S1, a laminate is produced (see FIG. 4A). Here, the contact layer 101, the first multilayer reflector 102, the first cladding layer 103, the active layer 104, the second cladding layer 105 including a selected oxidation layer 106S therein, and the second multilayer reflector 107 are stacked (for example, are caused to experience epitaxial growth at a growth temperature of 605° C.) in this order on the substrate 100 in a growth chamber by the metal organic chemical vapor deposition (MOCVD) method, for example, to thereby produce the laminate. Note that when the MOCVD is performed, trimethylgallium ((CH₃)₃Ga), for example, is used as raw material gas of gallium, trimethylaluminum ((CH₃)₃Al), for example, is used as raw material gas of aluminum, trimethylindium ((CH₃)₃In), for example, is used as raw material gas of indium, and trimethylarsine ((CH₃)₃As), for example, is used as raw material gas of As. Also, monosilane (SiH₄), for example, is used as raw material gas of silicon, and carbon tetrabromide (CBr₄), for example, is used as raw material gas of carbon.

In next Step S2, the mesa M is formed (see FIG. 4B). Specifically, a resist pattern is formed at a location on the laminate where the mesa M is formed, and the second multilayer reflector 107, the second cladding layer 105, the active layer 104, the first cladding layer 103, and the first multilayer reflector 102 are etched through reactive ion etching (RIE), for example, using the resist pattern as a mask to thereby form the mesa M. The etching depth at this time is such a depth that the contact layer 101 is exposed. Thereafter, the resist pattern is removed.

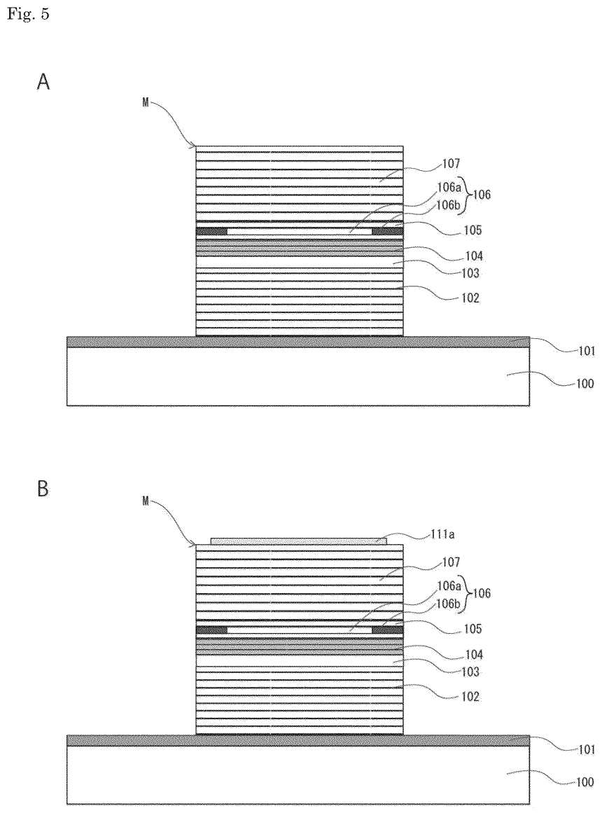

In Step S3, the oxidation constriction layer 106 is formed (see FIG. 5A). Specifically, the mesa M is exposed to a water vapor atmosphere, and the selected oxidation layer 106S (an AlAs layer, for example) is oxidized (selectively oxidized) from a lateral side to thereby form the oxidation constriction layer 106 with the surroundings of a non-oxidation region 106a surrounded by an oxidation region 106b.

In next Step S4, the second contact metal 111a is formed (see FIG. 5B). Specifically, the second contact metal 111a with a substantially circular shape in a plan view with a diameter that is smaller than the diameter of the mesa M by about 1 to 300 μm is formed at the top portion of the mesa M using the lift-off method, for example. The film formation of the second contact metal 111a is performed by the vacuum deposition method or the sputtering method, for example.

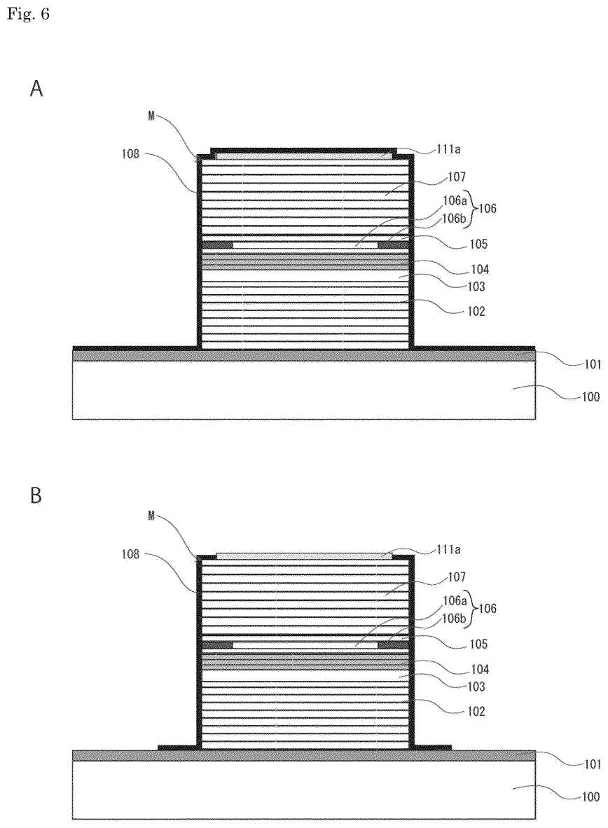

In next Step S5, the insulating film 108 is formed (see FIG. 6A). Specifically, the insulating film 108 is formed on the entire surface by the CVD method, the vacuum deposition method, or the sputtering method, for example.

In next Step S6, a portion of the insulating film 108 is removed (see FIG. 6B). Specifically, a part on the second contact metal 111a and a portion on the contact layer 101 of the insulating film 108 are removed by the RIE method with a solution containing hydrogen fluoride, for example. As a result, portions of the first contact metal 111a and the contact layer 101 are exposed.

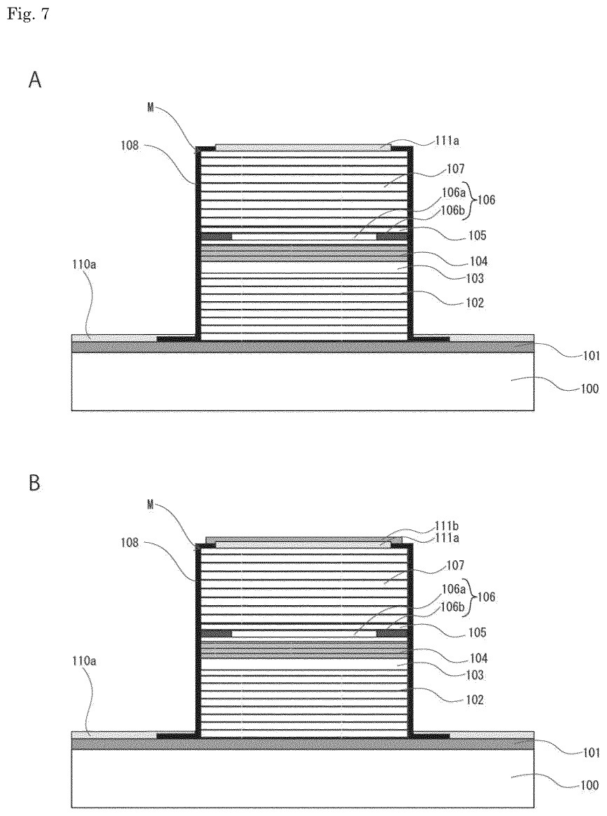

In next Step S7, the first contact metal 110a is formed (see FIG. 7A). Specifically, the first contact metal 110a is formed on the exposed contact layer 101 using the lift-off method, for example. The film formation of the first contact metal 110a is performed by the vacuum deposition method or the sputtering method, for example.

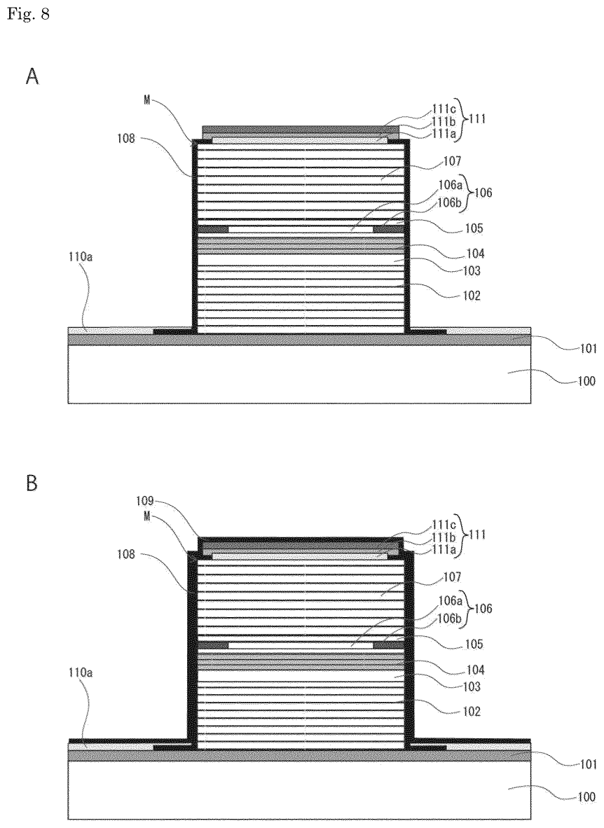

In next Step S8, the second pad metal 111b and the second plated metal 111c are formed. Specifically, the second pad metal 111b is formed on the second contact metal 111a using the lift off method, for example, first (see FIG. 7B). The film formation of the second pad metal 111b is performed by the vacuum deposition method or the sputtering method, for example. Then, the second plated metal 111c is formed on the second pad metal 111b using the plating method, for example (see FIG. 8A).

As a result, the stacked electrode 111 is formed on the mesa M.

In next Step S9, the insulating film 109 is formed (see FIG. 8B). Specifically, the insulating film 109 is formed on the entire surface by the CVD method, the vacuum deposition method, or the sputtering method, for example.

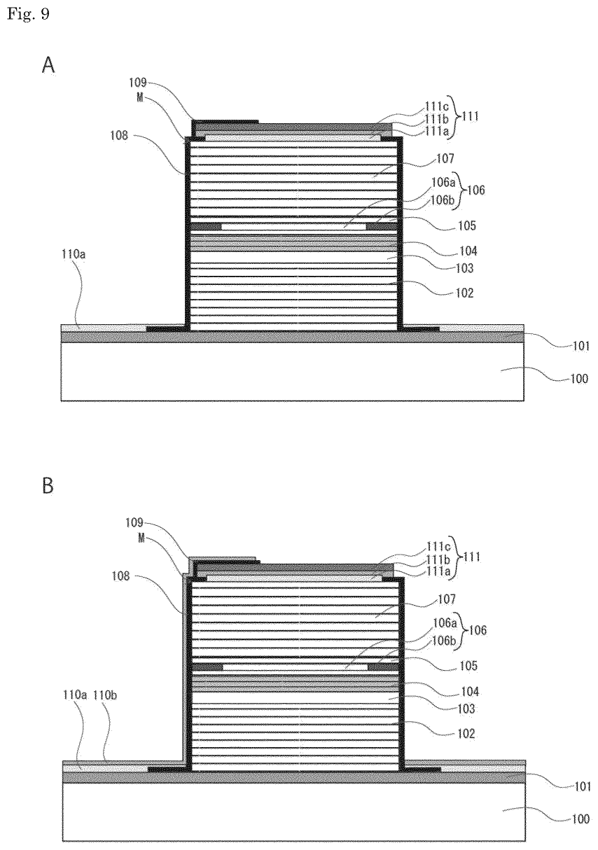

In next Step S10, a portion of the insulating film 109 is removed (see FIG. 9A). Specifically, a part of the insulating film 109 other than the location where the first electrode e1 is to be formed is removed by the RIE method with a solution containing hydrogen fluoride, for example.

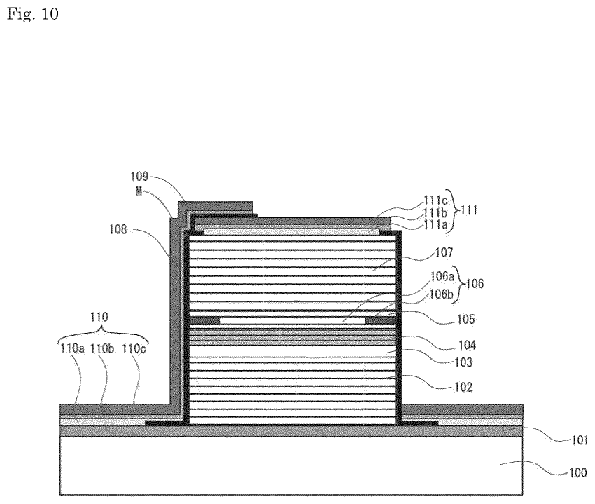

In last Step S11, the first pad metal 110b and the first plated metal 110c are formed. Specifically, the first pad metal 110b is formed on the first contact metal 110a and on the insulating films 108 and 109 using the lift-off method, for example (see FIG. 9B). The film formation of the first pad metal 111b is performed by the vacuum deposition method or the sputtering method, for example. Then, the first plated metal 110c is formed on the first pad metal 110b using the plating method, for example (see FIG. 10). As a result, the wiring 110 is formed.

### (Effects of Surface Emitting Laser)

The surface emitting laser 10 according to the first example of the first embodiment of the present technology includes the first structure S1 that includes the first multilayer reflector 102, the second structure S2 that includes the second multilayer reflector 107, the active layer 104 that is disposed between the first and second structures S1 and S2, the first electrode e1 that is electrically connected to the first structure S1, and the second electrode e2 that is electrically connected to the second structure S2, and the first and second electrodes e1 and e2 are provided in the second structure S2 in the state where the first and second electrodes e1 and e2 are insulated from each other.

In the surface emitting laser 10, the first and second electrodes e1 and e2 are provided in the second structure S2 in the state in which the first and second electrodes e1 and e2 are insulated from each other. In other words, both the first and second electrodes e1 and e2 are not provided in the surroundings of the light emitting portion (resonator) including the first and second structures S1 and S2 and the active layer 104. Therefore, it is not necessary to secure a connection region for connecting the electrode to the wiring in the surroundings of the light emitting portion. Therefore, according to the surface emitting laser 10, it is possible to provide a surface emitting laser capable of increasing the size of the light emitting portion while curbing an increase in size as a whole. Furthermore, according to the surface emitting laser 10, it is not necessary to secure the connection region in the surroundings of the light emitting portion, and it is also thus possible to dispose the light emitting portion with a higher density.

Incidentally, producing the anode electrode and the cathode electrode on the same surface side is typical for the VCSEL of the rear surface emitting type, for example. For example, PTL 1 and 2 propose a technology of setting the heights of the anode electrode and the cathode electrode to be substantially the same. However, according to PTL 1 and 2, one of the anode electrode and the cathode electrode is disposed in the surroundings of the light emitting portion (resonator), it is thus necessary to secure the connection region to connect the electrode to the wiring in the surroundings of the light emitting portion, and there is thus a problem that the entire size increases if the size of the light emitting portion is increased.

Additionally, an increase in output and size reduction are required when the VCSEL is used as a light source for sensing, for example. In order to increase an output, it is only necessary to increase the light emitting area (the size of the light emitting portion) of the VCSEL. In other words, it is only necessary to align the VCSEL in an array shape or to increase the aperture diameter (current constriction diameter) of the VCSEL. However, if such a structure is employed to increase an output, the anode electrode or the cathode electrode is present in the surroundings of the light emitting portion in the structure in the related art in the case where the anode electrode and the cathode electrode are present on the same surface side, in particular, in the VCSEL of the rear surface emitting type, a large connection region is thus needed for installation, and the entire size increases. In order to curb an increase in size as a whole, it is effective to minimize the area required for the connection region that is necessary to install the VCSEL. Although the size increases as a whole if the distance between the anode electrode and the cathode electrode is long, that is, if the area necessary to install one VCSEL is large, it is possible to increase the size of the light emitting portion while curbing an increase in size as a whole by minimizing the distance between the anode electrode and the cathode electrode.

The first and second electrodes e1 and e2 are disposed on the second structure S2 on the side opposite to the active layer 104. It is thus not necessary to secure the connection region at all in the surroundings of the light emitting portion.

The first and second electrodes e1 and e2 are disposed to be aligned in the stacked direction. In this case, excellent space utilization in the stacked direction is achieved.

The second electrode e2 is provided on the surface of the second structure S2 on the side opposite to the side of the active layer 104. In this manner, it is possible to obtain direct contact between the second electrode e2 and the second structure S2.

The first and second electrodes e1 and e2 are stacked via the insulating film 109. In this manner, it is possible to stack the first and second electrodes e1 and e2 in a state where the first and second electrodes e1 and e2 are insulated from each other.

The first electrode e1 is smaller than the second electrode e2. In this manner, it is possible to expose a portion of the second electrode e2 and to cause the portion to serve as a connection region for flip-chip, for example.

The first electrode e1 is another portion (an end portion, for example) of the wiring 110, a portion of which is connected to the first structure S1. In this manner, it is possible to reduce the number of components and to simplify the manufacturing process.

The mesa M that has the top portion in the second structure S2 is configured by at least the second structure S2 and the active layer 104 from among a portion of the first structure S1, the second structure S2, and the active layer 104, and the wiring 110 is provided along the mesa M via the insulating films 108 and 109. In this manner, it is possible to dispose the wiring 110 along the mesa M in a state in which the wiring 110 is insulated from the second structure S2.

A portion of the wiring 110 is in contact with the surface of the first structure S1 exposed in the surroundings of the mesa M. In this manner, it is possible to reliably electrically connect the first structure S1 to the first electrode e1.

The first structure S1 further includes the substrate 100 that is disposed on the first multilayer reflector 102 on the side opposite to the side of the active layer 104 and the contact layer 101 that is disposed between the substrate 100 and the active layer 104 and is disposed in the surroundings of the mesa M, and a portion of the wiring 110 is in contact with the contact layer 101. In this manner, it is possible to reduce the resistance at the portion in contact with the portion of the wiring 110.

### <2. Surface Emitting Laser According to Second Example of First Embodiment of Present Technology>

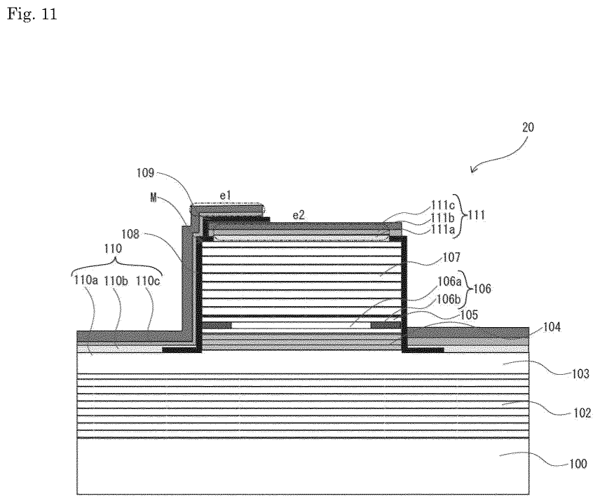

FIG. 11 is a sectional view of a surface emitting laser 20 according to a second example of the first embodiment of the present technology. The surface emitting laser 20 according to the second example has a configuration that is similar to that of the surface emitting laser 10 according to the first example other than that the surface emitting laser 20 has an intra-cavity structure.

In the surface emitting laser 20, the first cladding layer 103 of the first structure is exposed in the surroundings of the mesa M, and a portion of the wiring 110 is in contact with the first cladding layer 103. In the surface emitting laser 20, the mesa M is configured by a portion of the first cladding layer 103, the active layer 104, the second cladding layer 105 including the oxidation constriction layer 106, and the second multilayer reflector 107 in an example.

The surface emitting laser 20 can be manufactured by a production method that is almost similar to the method for manufacturing the surface emitting laser 10 according to the first example.

According to the surface emitting laser 20, it is possible to obtain effects that are similar to those of the surface emitting laser 10 according to the first example.

### <3. Surface Emitting Laser According to Third Example of First Embodiment of Present Technology>

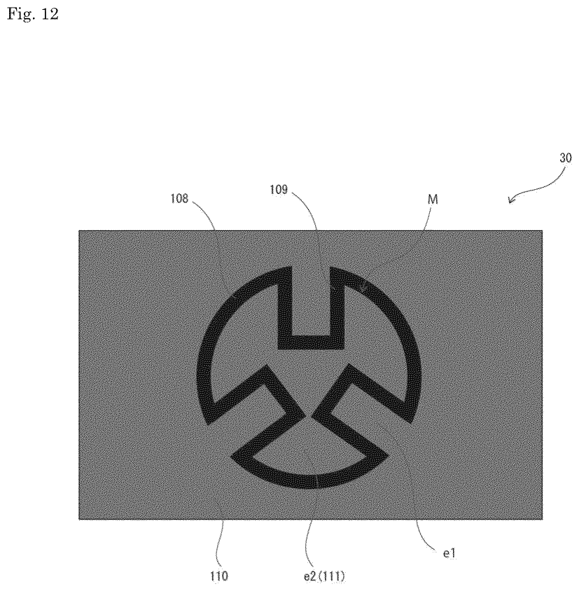

FIG. 12 is a plan view of a surface emitting laser 30 according to a third example of the first embodiment of the present technology.

The surface emitting laser 30 according to the third example has a configuration that is similar to that of the surface emitting laser 10 according to the first example other than that the surface emitting laser 30 includes a plurality of (three, for example) first electrodes e1 as illustrated in FIG. 12.

The surface emitting laser 30 can be manufactured by a production method that is almost similar to the method for manufacturing the surface emitting laser 10 according to the first example.

According to the surface emitting laser 30, it is possible to obtain effects that are similar to those of the surface emitting laser 10 according to the first example, and it is possible to increase the contact area with a terminal of the laser driver on the negative electrode side, for example, and to reduce the resistance because the number of electrodes of the first electrode e1 is large.

### <4. Surface Emitting Laser According to Fourth Example of First Embodiment of Present Technology>

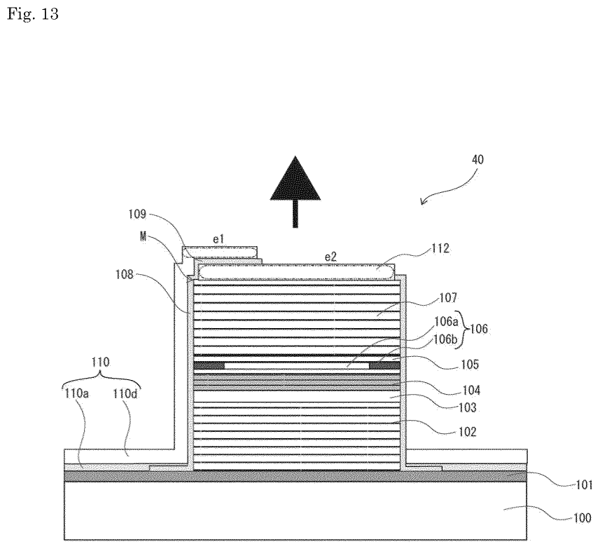

FIG. 13 is a sectional view of a surface emitting laser 40 according to a fourth example of the first embodiment of the present technology.

The surface emitting laser 40 according to the fourth example has a configuration that is similar to that of the surface emitting laser 10 according to the first example other than that the wiring 110 including the first electrode e1 is configured of the contact metal 110a and a transparent conductive film 110d and a transparent conductive film 112 is provided instead of the stacked electrode 111 as the second electrode e2 as illustrated in FIG. 13.

Each transparent conductive film is made of, for example, ITO, ITiO, or Zno. The insulating film 109 is made of a dielectric substance such as SiO₂, SiN, or SiON, for example, for example, and has translucency.

In the surface emitting laser 40, the first and second electrodes e1 and e2 provided at the top portion of the mesa M and the insulating film 109 have translucency, and it is thus possible to configure a surface emitting laser of a front surface emitting type that emits light from the top portion of the mesa M.

The surface emitting laser 40 can be manufactured by a production method that is almost similar to the method for manufacturing the surface emitting laser 10 according to the first example.

According to the surface emitting laser 40, it is possible to obtain effects that are similar to those of the surface emitting laser 10 according to the first example.

Note that the wiring 110 may be configured only of the transparent conductive film 110d.

### <5. Surface Emitting Laser According to Fifth Example of First Embodiment of Present Technology>

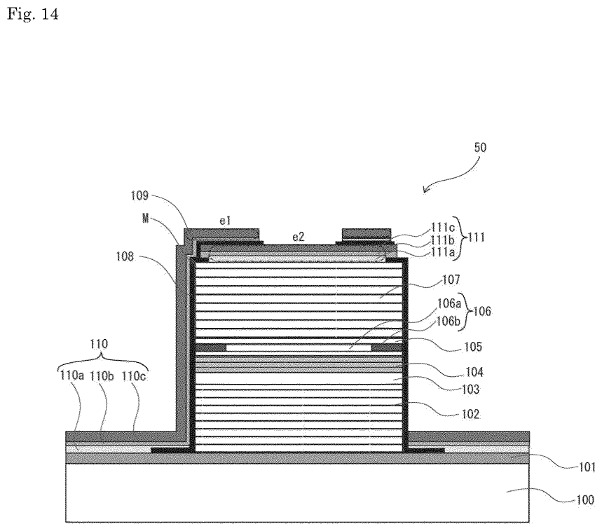

FIG. 14 is a sectional view of a surface emitting laser 50 according to a fifth example of the first embodiment of the present technology.

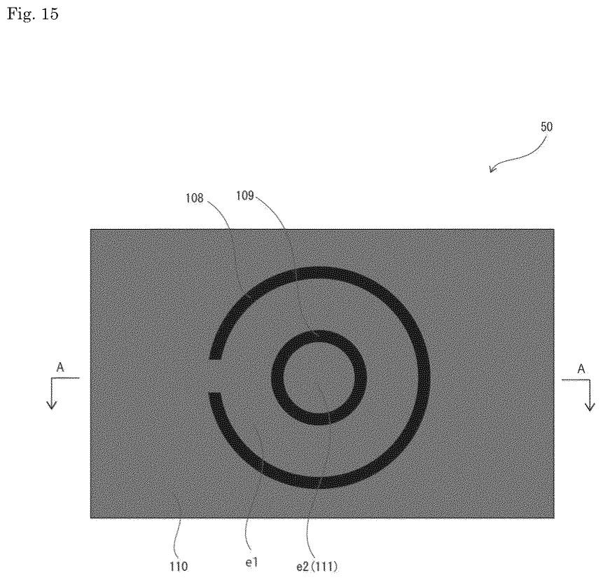

FIG. 15 is a plan view of the surface emitting laser 50 according to the fifth example of the first embodiment of the present technology. FIG. 14 is a sectional view along the line A-A in FIG. 15.

The surface emitting laser 50 according to the fifth example has a configuration that is substantially similar to that of the surface emitting laser 10 according to the first example other than that the first and second electrodes e1 and e2 are provided such that the first electrode e1 surrounds the second electrode e2 in a plan view as illustrated in FIGS. 14 and 15.

In the surface emitting laser 50, the second electrode e2 has a substantially circular shape in a plan view, and the first electrode e1 has a substantially annular shape that is substantially concentric with the second electrode e2 in an example.

The surface emitting laser 50 can be manufactured by a production method that is almost similar to the method for manufacturing the surface emitting laser 10 according to the first example.

According to the surface emitting laser 50, it is possible to obtain effects that are similar to those of the surface emitting laser 10 according to the first example, to increase the contact area between the first electrode e1 and the terminal of the laser driver on the side of the negative electrode, for example, and to reduce the resistance.

### <6. Surface Emitting Laser According to Sixth Example of First Embodiment of Present Technology>

### (Configuration of Surface Emitting Laser)

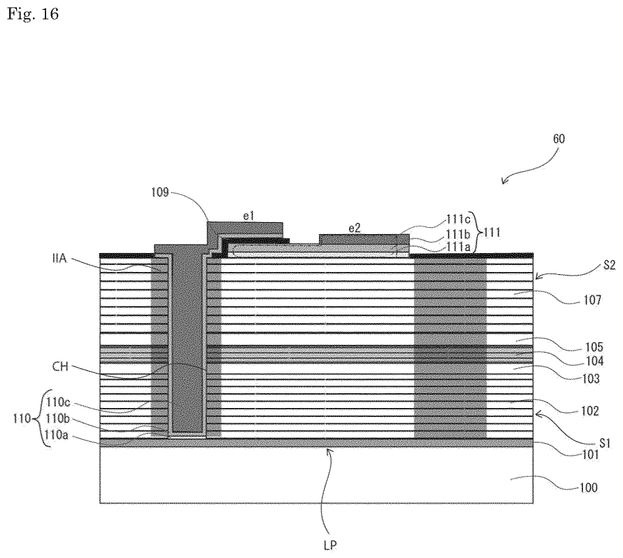

FIG. 16 is a sectional view of a surface emitting laser 60 according to a sixth example of the first embodiment of the present technology. The surface emitting laser 60 according to the sixth example has a configuration that is substantially similar to that of the surface emitting laser 10 according to the first example other than that the surface emitting laser 60 does not include the mesa M.

In the surface emitting laser 60, the wiring 110 is provided to penetrate through at least the second structure S2 and the active layer 104 from among the first structure S1, the second structure S2, and the active layer 104 and is surrounded by an ion injection region IIA serving as an insulated region provided across a portion of the first structure S1 (the first multilayer reflector 102 and the first cladding layer 103, for example), the second structure S2, and the active layer 104 from among the first structure S1, the second structure S2, and the active layer 104 in an example. The ion injection region IIA is provided in an annular shape as a whole, for example, and a conductive region located therein serves as a light emitting portion LP. In other words, the light emitting portion LP is surrounded by the ion injection region IIA in an example.

In the surface emitting laser 60, a contact hole CH that penetrates through the second structure S2 and the active layer 104 and has a bottom surface configured by a surface (upper surface) of the contact layer 101 is provided in an example. The first contact metal 110a is disposed in contact with the contact layer 101 inside the contact hole CH. A portion of the first pad metal 110b is disposed along the inner surface of the contact hole CH to be in contact with the first contact metal 110a, and another portion is disposed on the second electrode e2 via the insulating film 109.

The first plated metal 110c is disposed in contact with the first pad metal 110b inside and outside the contact hole CH. The first electrode e1 is configured by portions of the first plated metal 110c and the first pad metal 110b disposed on the second electrode e2 via the insulating film 109.

### <<Method for Manufacturing Surface Emitting Laser>>

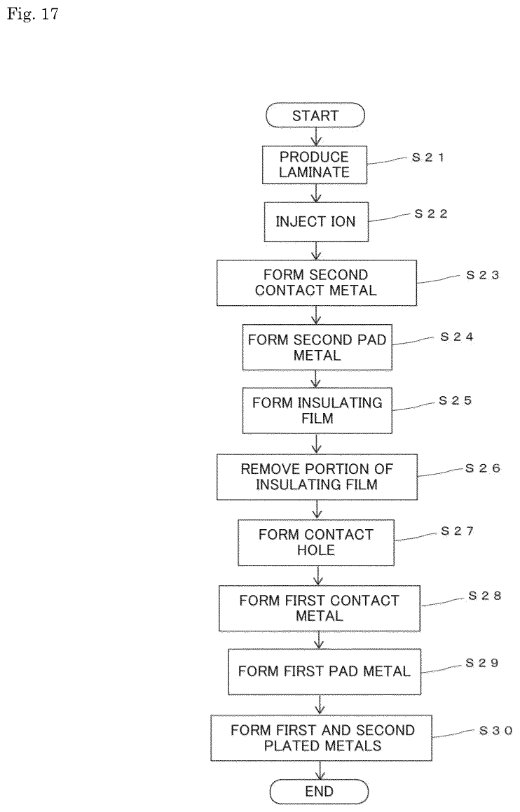

Hereinafter, a method for manufacturing the surface emitting laser 60 will be described with reference to the flowchart (Steps S21 to S30) in FIG. 17. Here, a plurality of surface emitting lasers 60 are simultaneously produced on a single wafer that is a base material of the substrate 100 by a semiconductor manufacturing method using a semiconductor manufacturing device in an example. Then, the series of plurality of integrated surface emitting lasers 60 are separated from each other to thereby obtain a plurality of surface emitting lasers 60 with a chip shape.

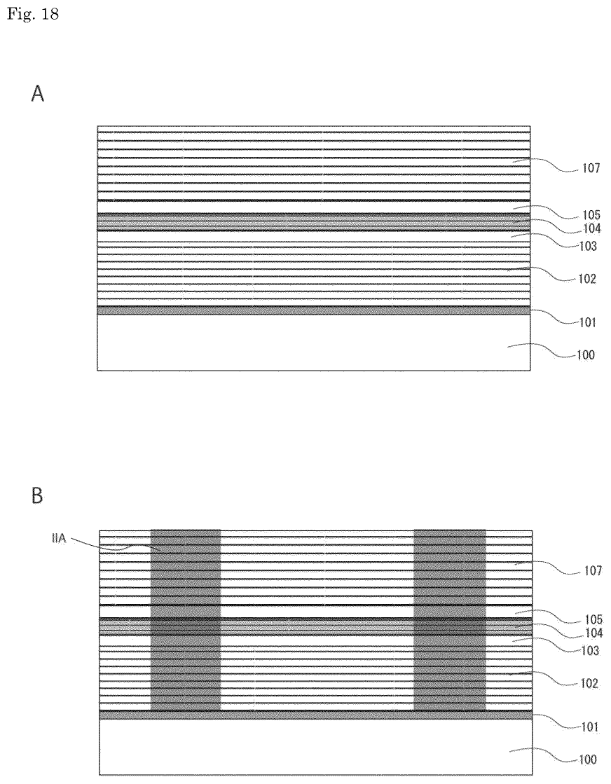

In first Step S21, a laminate is produced (see FIG. 18A). Here, the contact layer 101, the first multilayer reflector 102, the first cladding layer 103, the active layer 104, the second cladding layer 105, and the second multilayer reflector 107 are stacked (caused to experience epitaxial growth at a growth temperature of 605° C., for example) in this order on the substrate 100 in a growth chamber by the metal organic chemical vapor deposition (MOCVD) to thereby produce the laminate. Note that when the MOCVD is performed, trimethylgallium ((CH₃)₃Ga), for example, is used as raw material gas of gallium, trimethylaluminum ((CH₃)₃Al), for example, is used as raw material gas of aluminum, trimethylindium ((CH₃)₃In), for example, is used as raw material gas of indium, and trimethylarsine ((CH₃)₃As), for example, is used as raw material gas of As. Also, monosilane (SiH₄), for example, is used as raw material gas of silicon, and carbon tetrabromide (CBr₄), for example, is used as raw material gas of carbon.

In next Step S22, ion injection is performed (see FIG. 18B). Specifically, a protective film that covers a location of the laminate other than the location where the ion injection region IIA is to be formed is formed first. Then, B ions and H ions, for example, are injected to the laminate using the protective film as a mask to thereby form the ion injection region IIA surrounding the light emitting portion.

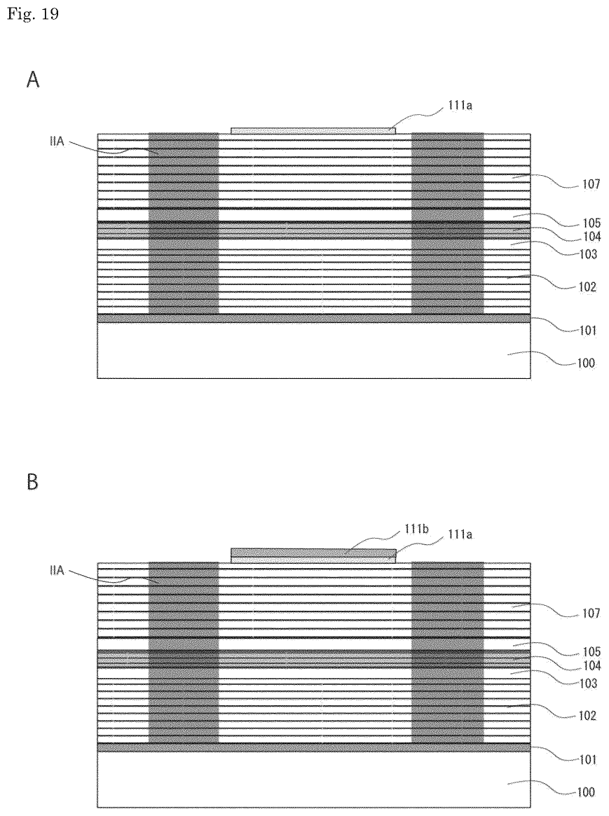

In next Step S23, the second contact metal 111a is formed (see FIG. 19A). Specifically, the second contact metal 111a with a substantially circular shape in a plan view is formed using the lift off method, for example. The film formation of the second contact metal 111a is performed by the vacuum deposition method or the sputtering method, for example.

In next Step S24, the second pad metal 111b is formed (see FIG. 19B). Specifically, the second pad metal 111b is formed on the second contact metal 111a using the lift off method, for example. The film formation of the second pad metal 111b is performed by the vacuum deposition method or the sputtering method, for example.

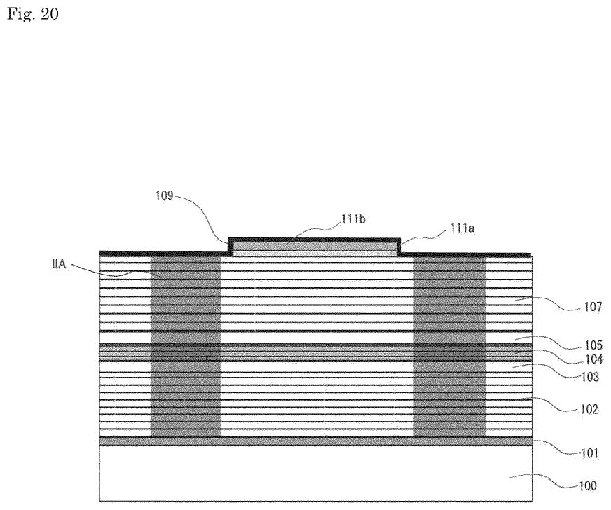

In next Step S25, the insulating film 109 is formed (see FIG. 20). Specifically, the insulating film 109a is formed on the entire surface by the CVD method, the vacuum deposition method, or the sputtering method, for example.

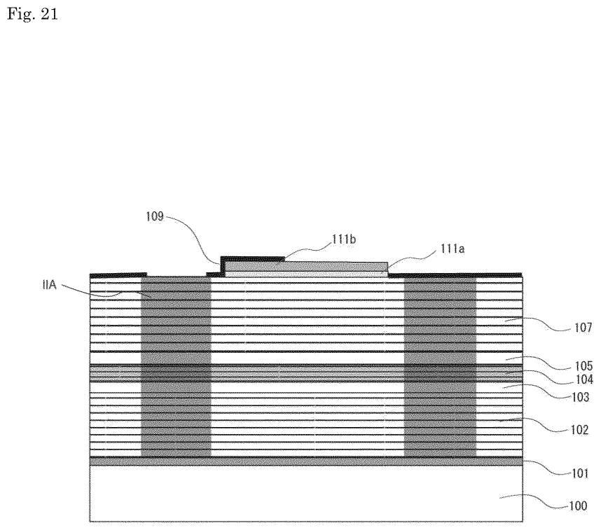

In next Step S26, a portion of the insulating film 109 is removed (see FIG. 21). Specifically, the insulating film 109 covering a portion of the ion injection region IIA of the laminate and the insulating film 109 covering a portion of the second pad metal 111b are removed by the RIE method with a solution containing hydrogen fluoride, for example.

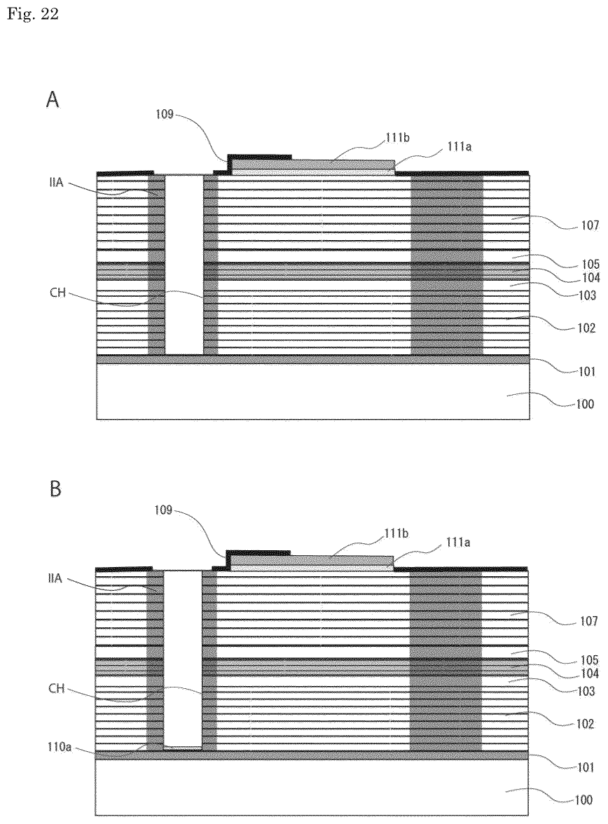

In next Step S27, the contact hole CH is formed (see FIG. 22A). Specifically, a central region that is a portion of the ion injection region IIA that has been exposed by removing the insulating film 109 is removed though etching (dry etching, for example), and the contact hole CH including the upper surface of the contact layer 101 as the bottom surface is formed. The contact hole CH is surrounded by the ion injection region IIA.

In next Step S28, the first contact metal 110a is formed (see FIG. 22B). Specifically, the first contact metal 110a is formed on the bottom surface of the contact hole CH using the lift-off method, for example. The film formation of the first contact metal 110a is performed by the vacuum deposition method or the sputtering method, for example.

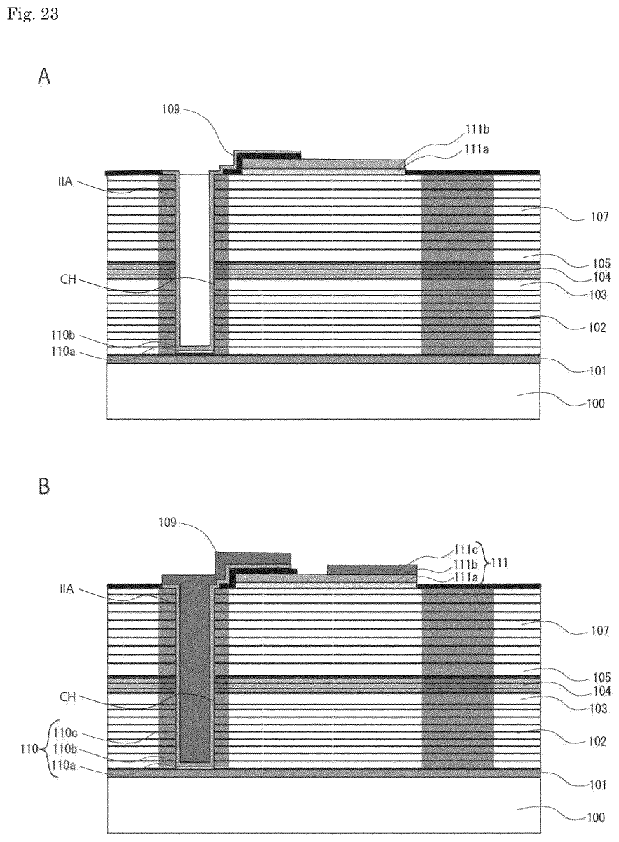

In next Step S29, the first pad metal 110b is formed (see FIG. 23A). Specifically, the first pad metal 110b is formed on the first contact metal 110a, on the inner surface of the contact hole CH, and on the insulating film 109 using the lift-off method, for example. The film formation of the first pad metal 110b is performed by the vacuum deposition method or the sputtering method, for example.

In last Step S30, the first and second plated metals 110c and 111c are formed (see FIG. 23B). Specifically, the first plated metal 110c is formed on the first pad metal 110b and the second plated metal 111c is formed on the exposed portion of the second pad metal 111b using the plating method, for example.

### <<Effects of Surface Emitting Laser>>

According to the surface emitting laser 60 described above, it is possible to obtain effects that are similar to those of the surface emitting laser 10 according to the first example.

### <7. Surface Emitting Laser Array According to Seventh Example of First Embodiment of Present Technology>

### (Configuration of Surface Emitting Laser Array)

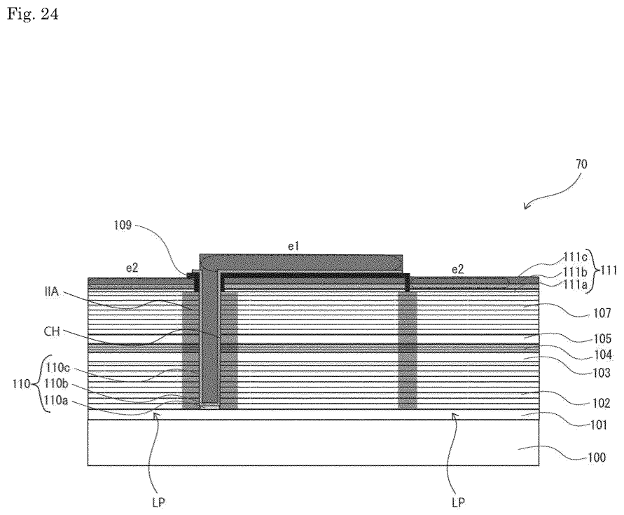

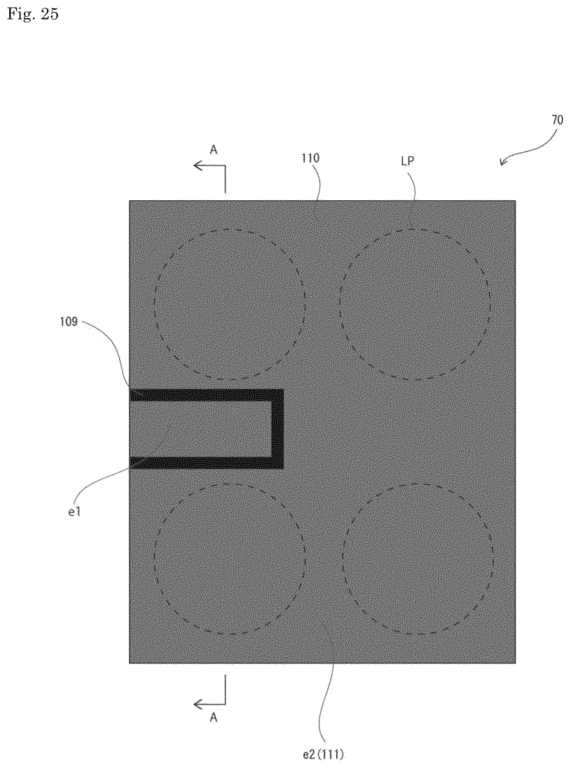

FIG. 24 is a sectional view of a surface emitting laser array 70 according to a seventh example of the first embodiment of the present technology. FIG. 25 is a plan view of the surface emitting laser array 70 according to the seventh example of the first embodiment of the present technology. FIG. 24 is a sectional view along the line A-A in FIG. 25.

The surface emitting laser array 70 according to the seventh example has a configuration that is substantially similar to that of the surface emitting laser 60 according to the sixth example other than that the first and second electrodes e1 and e2 are provided commonly in a plurality of light emitting portions LP (surface emitting lasers).

In the surface emitting laser array 70, the plurality of light emitting portions LP are sectioned by, for example, the ion injection region IIA.

### <<Method for Manufacturing Surface Emitting Laser>>

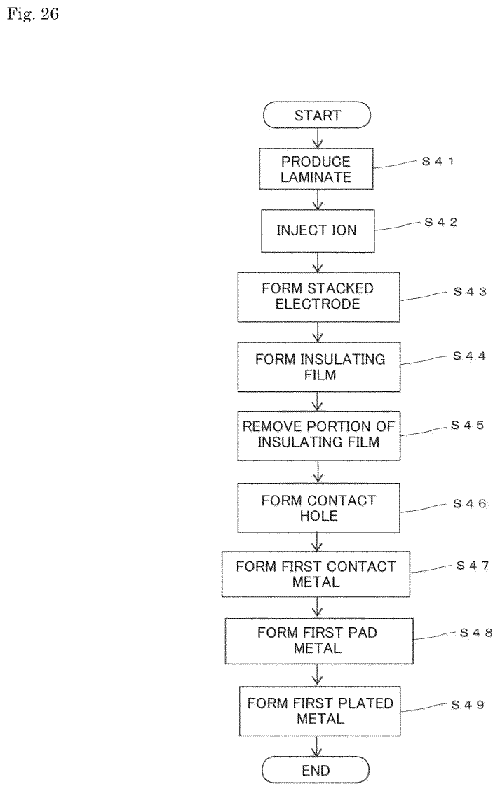

Hereinafter, a method for manufacturing the surface emitting laser array 70 will be described with reference to the flowchart (Steps S41 to S49) in FIG. 26. Here, a plurality of surface emitting laser arrays 70 are simultaneously produced on a single wafer that is a base material of the substrate 100 by the semiconductor manufacturing method using a semiconductor manufacturing device in an example. Then, the series of plurality of integrated surface emitting laser arrays 70 are separated from each other to thereby obtain a plurality of surface emitting laser arrays 70 with a chip shape.

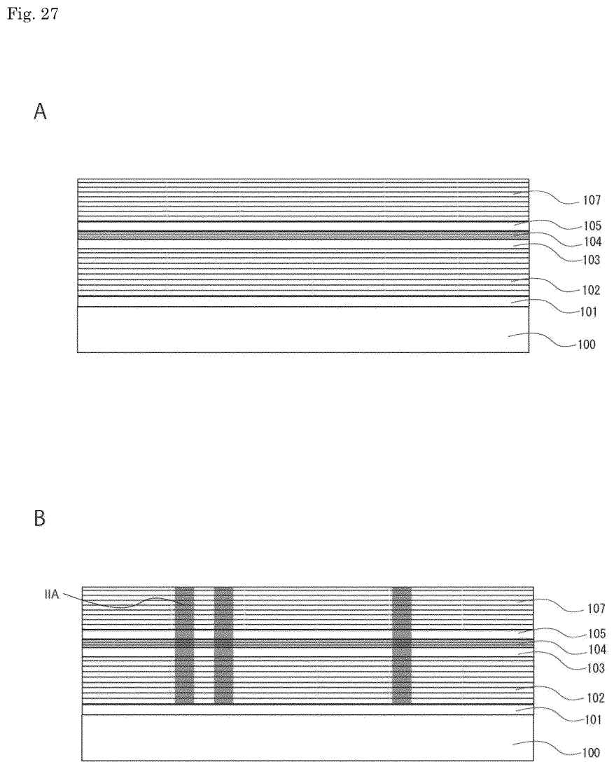

In first Step S41, a laminate is produced (see FIG. 27A). Here, the contact layer 101, the first multilayer reflector 102, the first cladding layer 103, the active layer 104, the second cladding layer 105, and the second multilayer reflector 107 are stacked (caused to experience epitaxial growth at a growth temperature of 605° C., for example) in this order on the substrate 100 in a growth chamber by the metal organic chemical vapor deposition (MOCVD) to thereby produce the laminate. Note that when the MOCVD is performed, trimethylgallium ((CH₃)₃Ga), for example, is used as raw material gas of gallium, trimethylaluminum ((CH₃)₃Al), for example, is used as raw material gas of aluminum, trimethylindium ((CH₃)₃In), for example, is used as raw material gas of indium, and trimethylarsine ((CH₃)₃As), for example, is used as raw material gas of As. Also, monosilane (SiH₄), for example, is used as raw material gas of silicon, and carbon tetrabromide (CBr₄), for example, is used as raw material gas of carbon.

In next Step S42, ion injection is performed (see FIG. 27B). Specifically, a protective film that covers a location of the laminate other than the location where the ion injection region IIA is to be formed is formed first. Then, B ions and H ions, for example, are injected to the laminate using the protective film as a mask to thereby form the ion injection region IIA sectioning the plurality of light emitting portions LP.

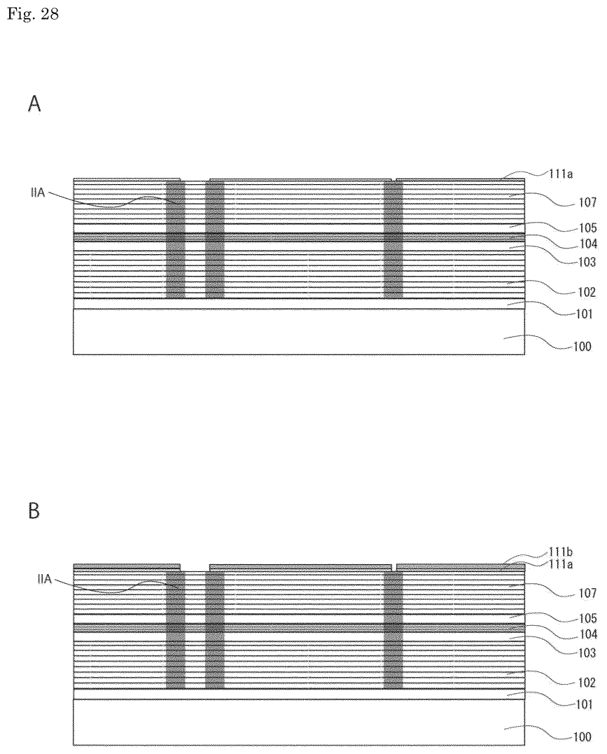

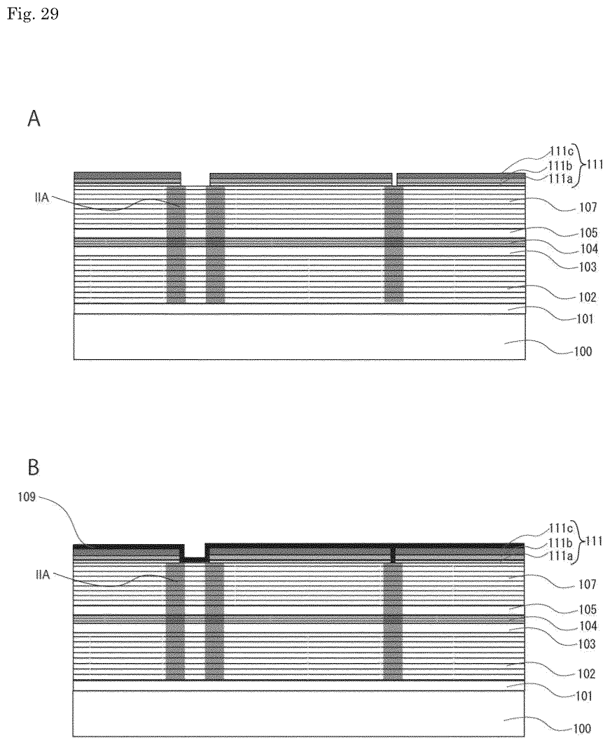

In next Step S43, the stacked electrode 111 is formed. First, the second contact metal 111a is formed in each region where the light emitting portion LP is formed by the lift off method, for example (see FIG. 28A). Then, the second pad metal 111b is formed on each second contact metal 111a by the lift-off method, for example (see FIG. 28B). Finally, the second plated metal 111c is formed on each second pad metal 111b by the plating method, for example (see FIG. 29A).

In next Step S44, the insulating film 109a is formed (see FIG. 29B). Specifically, the insulating film 109 is formed on the entire surface by the CVD method, the vacuum deposition method, or the sputtering method, for example.

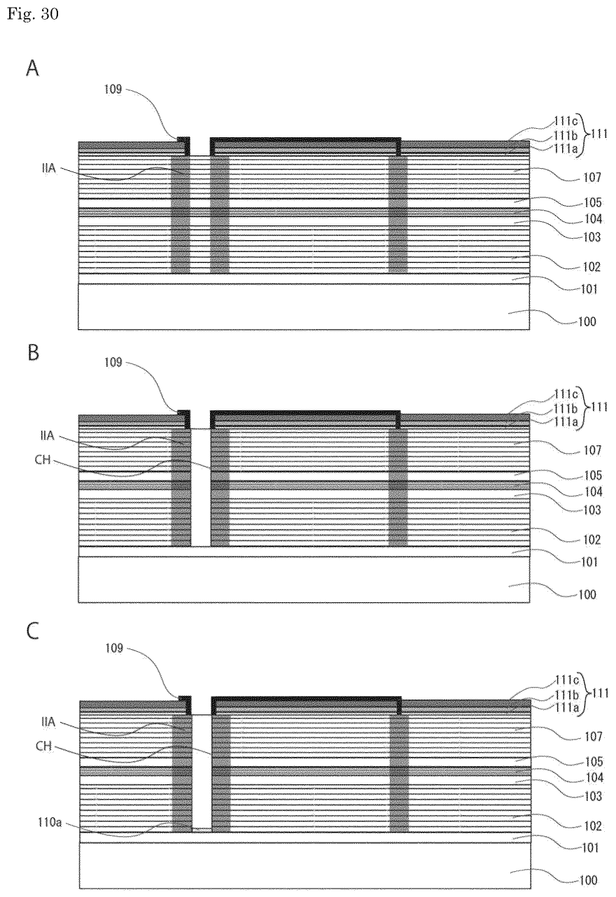

In next Step S45, a portion of the insulating film 109a is removed (see FIG. 30A). Specifically, the insulating film 109 covering a portion of the ion injection region IIA of the laminate and the insulating film 109 covering the part corresponding to each light emitting portion are removed by the RIE method with a solution containing hydrogen fluoride, for example. As a result, a portion of the ion injection region IIA and the stacked electrode 111 corresponding to each light emitting portion are exposed.

In next Step S46, the contact hole CH is formed (see FIG. 30B). Specifically, a central region that is a portion of the ion injection region IIA that has been exposed by removing the insulating film 109 is removed though etching (dry etching, for example), and the contact hole CH including the upper surface of the contact layer 101 as the bottom surface is formed. The contact hole CH is surrounded by the ion injection region IIA.

In next Step S47, the first contact metal 110a is formed (see FIG. 30C). Specifically, the first contact metal 110a is formed on the bottom surface of the contact hole CH using the lift-off method, for example. The film formation of the first contact metal 110a is performed by the vacuum deposition method or the sputtering method, for example.

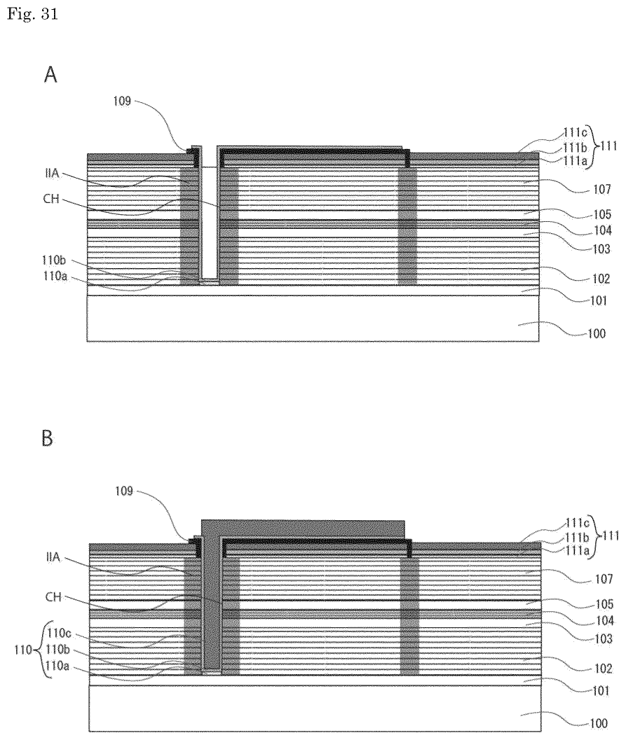

In next Step S48, the first pad metal 110b is formed (see FIG. 31A). Specifically, the first pad metal 110b is formed on the first contact metal 110a, on the inner surface of the contact hole CH, and on the insulating film 109 using the lift off method, for example. The film formation of the first pad metal 110b is performed by the vacuum deposition method or the sputtering method, for example.

In last Step S49, the first plated metal 110c is formed (see FIG. 31B). Specifically, the first plated metal 110c is formed on the first pad metal 110b using the plating method, for example.

### <<Effects of Surface Emitting Laser>>

According to the surface emitting laser array 70 described above, it is possible to obtain effects that are similar to those of the surface emitting laser 10 according to the first example and to collectively or independently drive the plurality of light emitting portions LP.

### <8. Surface Emitting Laser According to Eighth Example of First Embodiment of Present Technology>

### (Configuration of Surface Emitting Laser)

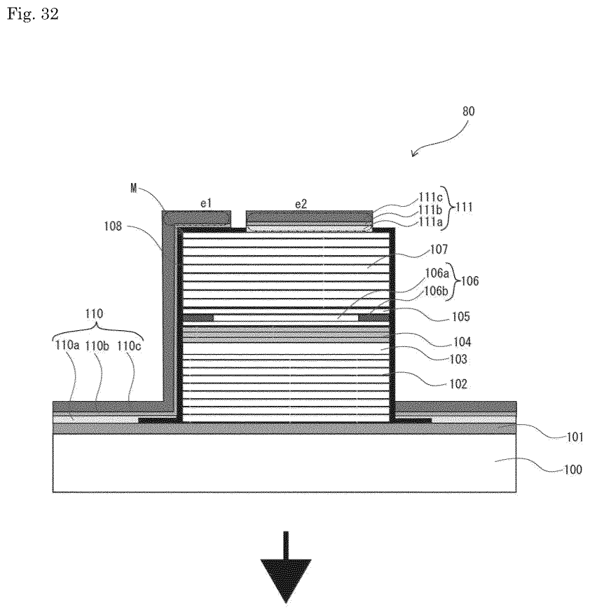

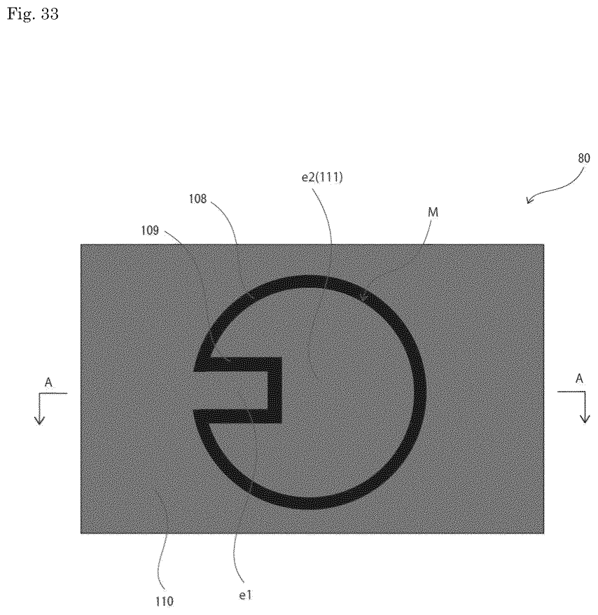

FIG. 32 is a sectional view of a surface emitting laser 80 according to an eighth example of the first embodiment of the present technology. FIG. 32 is a plan view of the surface emitting laser 80 according to the eighth example of the first embodiment of the present technology. FIG. 32 is a sectional view along the line A-A in FIG. 33.

The surface emitting laser 80 according to the eighth example has a configuration that is substantially similar to that of the surface emitting laser 10 according to the first example other than that the first and second electrodes e1 and e2 are aligned in a direction (the in-plane direction, for example) intersecting the stacked direction as illustrated in FIGS. 32 and 33.

In the surface emitting laser 80, the first electrode e1 is provided on the surface (the upper surface of the second multilayer reflector 107, for example) of the first structure S1 on the side opposite to the side of the active layer 104 via the insulating film 108.

### <<Method for Manufacturing Surface Emitting Laser>>

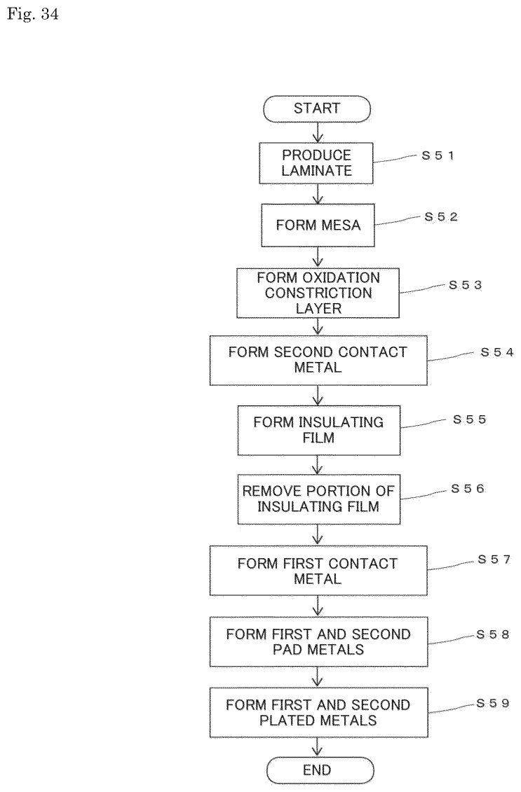

Hereinafter, a method for manufacturing the surface emitting laser 80 will be described with reference to the flowchart (Steps S51 to S59) in FIG. 34. Here, a plurality of surface emitting lasers 80 are simultaneously produced on a single wafer that is a base material of the substrate 100 by a semiconductor manufacturing method using a semiconductor manufacturing device in an example. Then, the series of plurality of integrated surface emitting lasers 80 are separated from each other to thereby obtain a plurality of surface emitting lasers 80 with a chip shape.

In first Step S51, a laminate is produced (see FIG. 4A). Here, the contact layer 101, the first multilayer reflector 102, the first cladding layer 103, the active layer 104, the second cladding layer 105 including a selected oxidation layer 106S therein, and the second multilayer reflector 107 are stacked (for example, are caused to experience epitaxial growth at a growth temperature of 605° C.) in this order on the substrate 100 in a growth chamber by the metal organic chemical vapor deposition (MOCVD) method to thereby produce the laminate. Note that when the MOCVD is performed, trimethylgallium ((CH₃)₃Ga), for example, is used as raw material gas of gallium, trimethylaluminum ((CH₃)₃Al), for example, is used as raw material gas of aluminum, trimethylindium ((CH₃)₃In), for example, is used as raw material gas of indium, and trimethylarsine ((CH₃)₃As), for example, is used as raw material gas of As. Also, monosilane (SiH₄), for example, is used as raw material gas of silicon, and carbon tetrabromide (CBr₄), for example, is used as raw material gas of carbon.

In next Step S52, the mesa M is formed (see FIG. 4B). Specifically, a resist pattern is formed at a location of the laminate where the mesa M is to be formed by photolithography, and the second multilayer reflector 107, the second cladding layer 105, the active layer 104, and the first cladding layer 103 are etched through reactive ion etching (RIE) using the resist pattern as a mask to thereby form the mesa M. The etching depth at this time is such a depth that the contact layer 101 is exposed. Thereafter, the resist pattern is removed.

In Step S53, the oxidation constriction layer 106 is formed (see FIG. 5A). Specifically, the mesa M is exposed to a water vapor atmosphere, and the selected oxidation layer 106S (an AlAs layer, for example) is oxidized (selectively oxidized) from a lateral side to thereby form the oxidation constriction layer 106 with the surroundings of a non-oxidation region 106a surrounded by an oxidation region 106b.

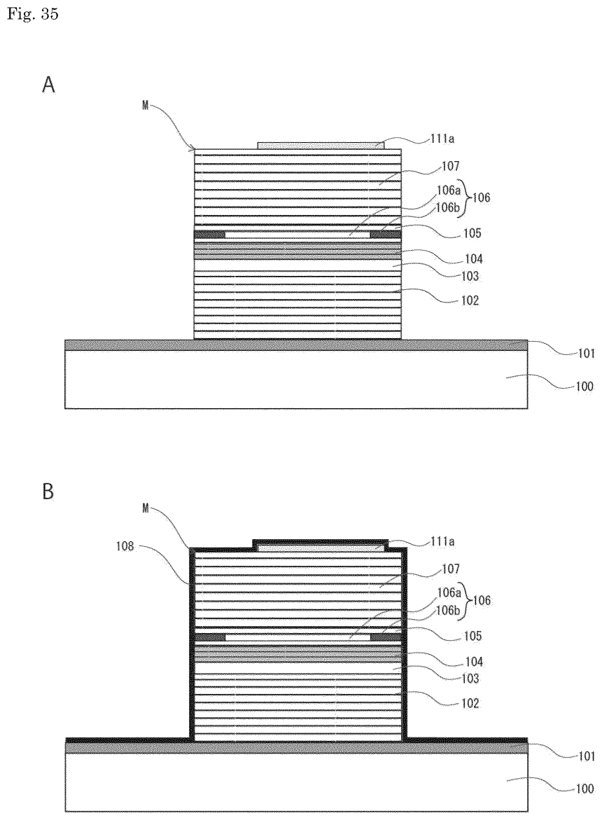

In next Step S54, the second contact metal 111a is formed (see FIG. 35A). Specifically, the second contact metal 111a with a substantially circular shape in a plan view is formed on the top portion of the mesa M at a position deviating from the center of the top portion using the lift-off method, for example. The film formation of the second contact metal 111a is performed by the vacuum deposition method or the sputtering method, for example.

In next Step S55, the insulating film 108 is formed (see FIG. 35B). Specifically, the insulating film 108 is formed on the entire surface by the CVD method, the vacuum deposition method, or the sputtering method, for example.

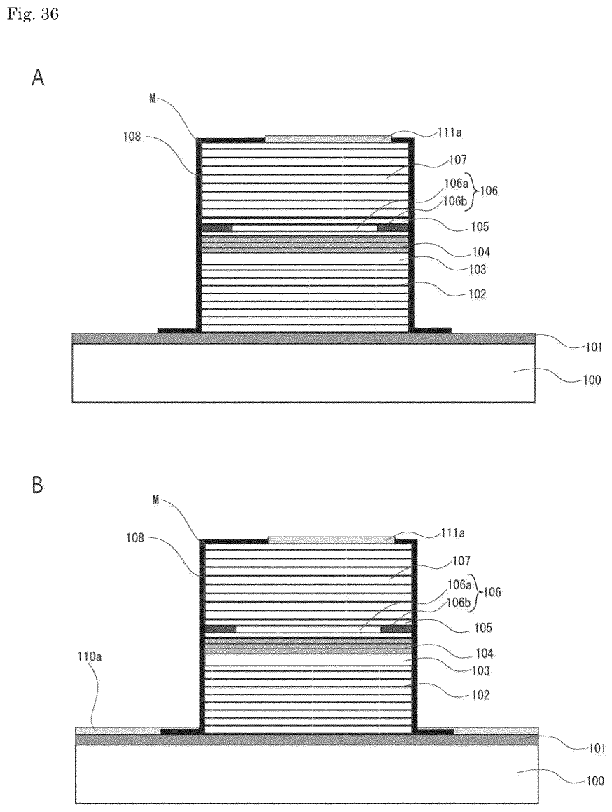

In next Step S56, a portion of the insulating film 108 is removed (see FIG. 36A). Specifically, a part on the second contact metal 111a and a portion on the contact layer 101 of the insulating film 108 are removed by the RIE method with a solution containing hydrogen fluoride, for example. As a result, portions of the first contact metal 111a and the contact layer 101 are exposed.

In next Step S57, the first contact metal 110a is formed (see FIG. 36B). Specifically, the first contact metal 110a is formed on the exposed contact layer 101 using the lift-off method, for example. The film formation of the first contact metal 110a is performed by the vacuum deposition method or the sputtering method, for example.

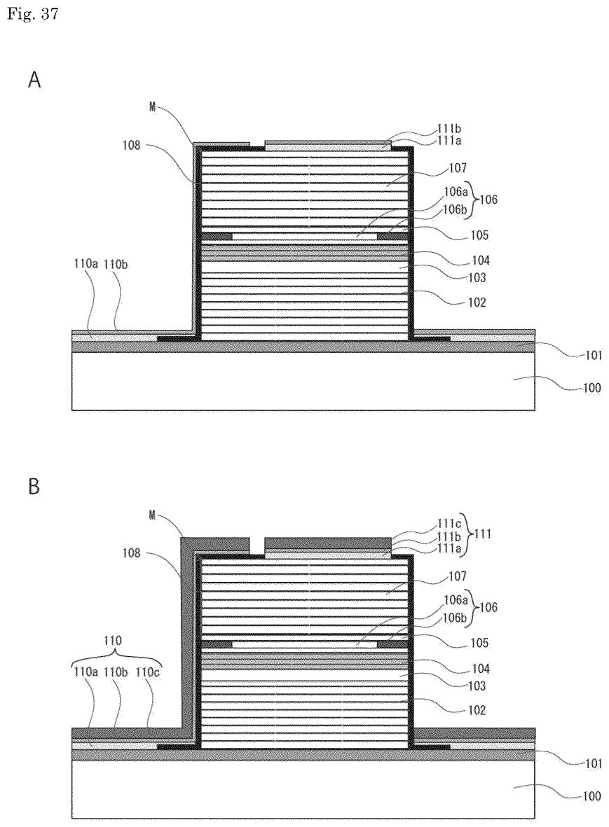

In next Step S58, the first and second pad metals 110b and 111b are formed (see FIG. 37A). Specifically, the first pad metal 110b is formed on the first contact metal 110a and the insulating film 108, and the second pad metal 111b is formed on the second contact metal 111a using the lift-off method, for example.

In last Step S59, the first and second plated metals 110c and 111c are formed (see FIG. 37B). Specifically, the first plated metal 110c is formed on the first pad metal 110b, and the second plated metal 111c is formed on the second pad metal 111b using the plating method, for example.

### <<Effects of Surface Emitting Laser>>

According to the surface emitting laser 80 described above, it is possible to obtain effects that are similar to those of the surface emitting laser 10 according to the first example, and it is possible to simplify the manufacturing process.

### <9. Light Source Device According to First Example of Second Embodiment>

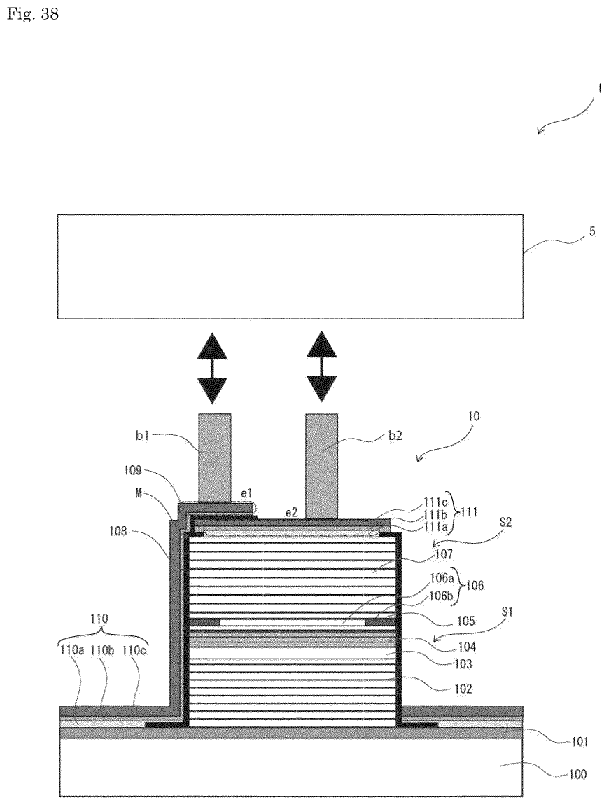

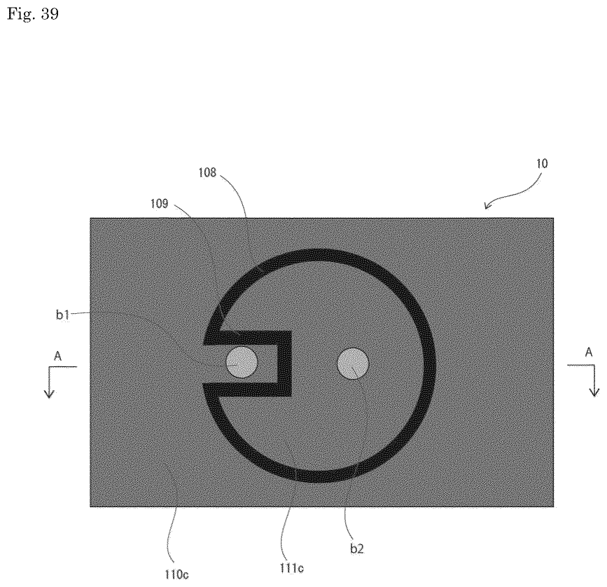

FIG. 38 is a sectional view illustrating a state before bonding of a light source device 1 according to a first example of a second embodiment of the present technology. FIG. 39 is a plan view of a surface emitting laser 10 of the light source device 1 according to the first example of the second embodiment of the present technology.

The light source device 1 according to the first example includes the surface emitting laser 10 and a laser driver 5 that is electrically connected to each of the first and second electrodes e1 and e2 of the surface emitting laser 10 via a conductive bump as illustrated in FIGS. 38 and 39.

The surface emitting laser 10 includes conductive bumps b1 and b2 attached to the first and second electrodes e1 and e2, respectively.

Each conductive bump is, for example, a metal bump and is aligned in the in-plane direction.

The first electrode e1 is connected to a terminal of a laser driver on a side of a negative electrode via the conductive bump b1 in an example. The second electrode e2 is connected to a terminal of the laser driver on a side of a positive electrode via the conductive bump b2 in an example.

The laser driver 5 includes, for example, a driver IC and is mounted on a print wiring substrate. The driver IC includes, for example, an NMOS driver that controls a voltage to be applied to the surface emitting laser 10.

In the light source device 1, the surface emitting laser 10 and the laser driver 5 are connected through flip-chip.

### <10. Light Source Device According to Modification of First Example of Second Embodiment>

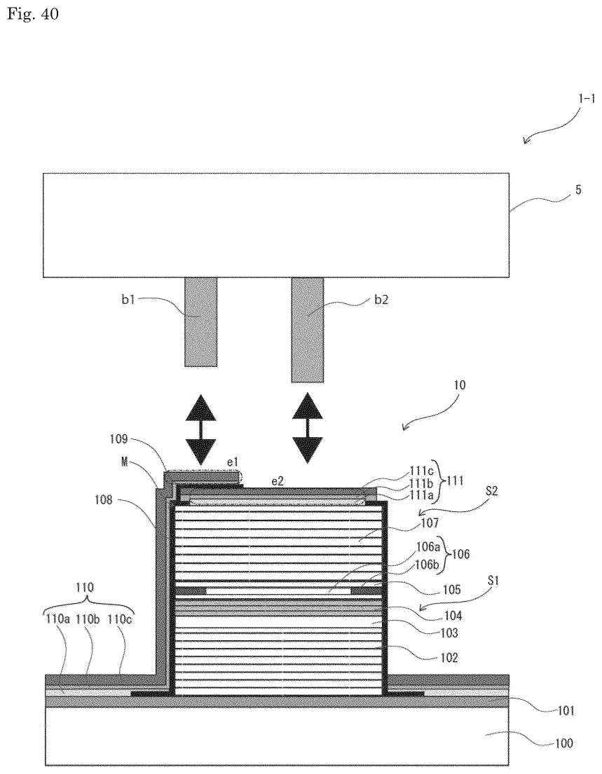

FIG. 40 is a sectional view illustrating a state before bonding of a light source device 1-1 according to a modification of the first example of the second embodiment of the present technology.

The light source device 1-1 according to the modification of the first example has a configuration that is similar to that of the light source device 1 according to the first example other than that the laser driver 5 includes the conductive bumps b1 and b2 as illustrated in FIG. 40.

### <11. Light Source Device According to Second Example of Second Embodiment>

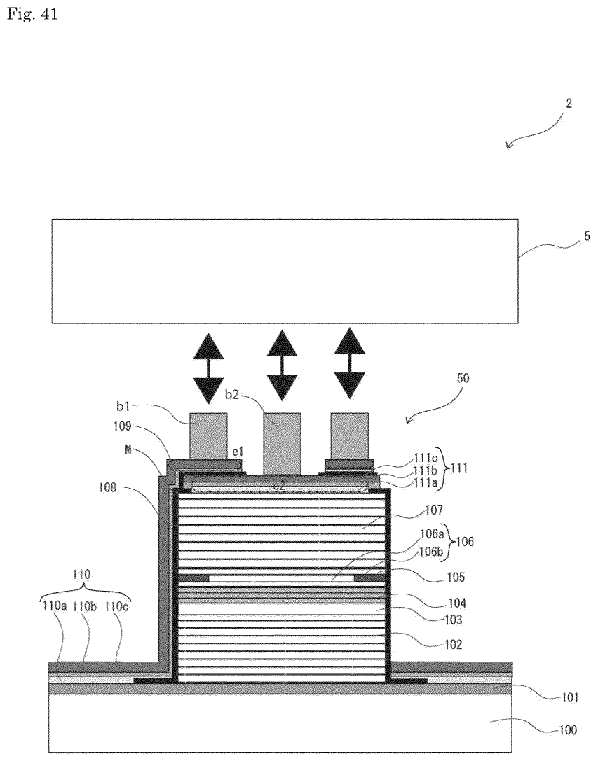

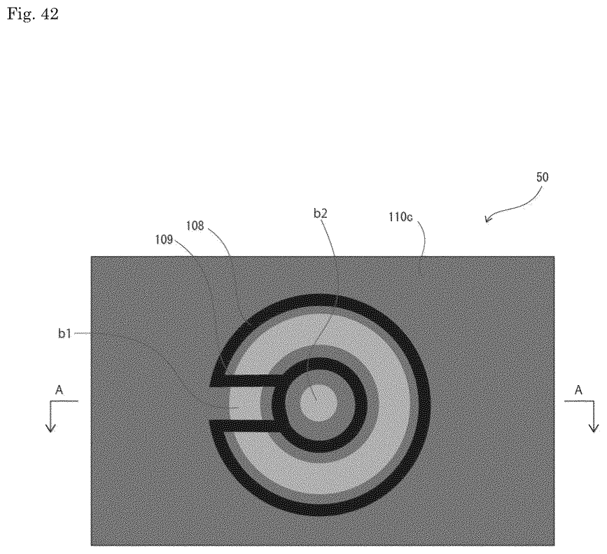

FIG. 41 is a sectional view illustrating a state before bonding of a light source device 2 according to a second example of the second embodiment of the present technology. FIG. 42 is a plan view of the surface emitting laser 50 of a light source device 2 according to the second example of the second embodiment of the present technology. FIG. 41 is a sectional view along the line A-A in FIG. 42.

The light source device 2 according to the second example includes the surface emitting laser 50 and the laser driver 5 that is electrically connected to each of the first and second electrodes e1 and e2 of the surface emitting laser 50 via a conductive bump as illustrated in FIGS. 41 and 42.

The surface emitting laser 50 includes conductive bumps b1 and b2 attached to the first and second electrodes e1 and e2, respectively. The conductive bumps b1 and b2 are provided such that the conductive bump b1 surrounds the conductive bump b2 in a plan view.

Each conductive bump is, for example, a metal bump.

The first electrode e1 is connected to a terminal of a laser driver on a side of a negative electrode via the conductive bump b1 in an example. The second electrode e2 is connected to a terminal of the laser driver on a side of a positive electrode via the conductive bump b2 in an example.

In the light source device 2, the surface emitting laser 50 and the laser driver 5 are connected through flip-chip.

### <12. Light Source Device According to Modification of Second Example of Second Embodiment>

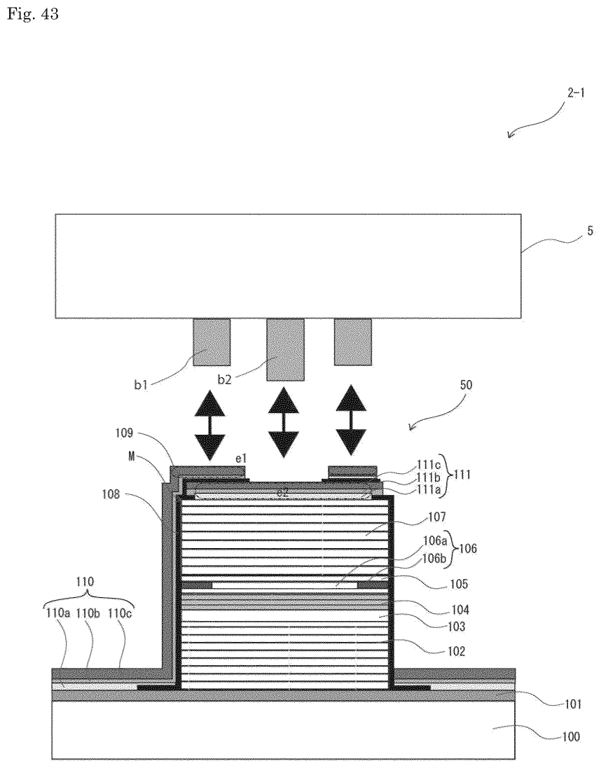

FIG. 43 is a sectional view illustrating a state before bonding of a light source device 2-1 according to a modification of the second example of the second embodiment of the present technology.

The light source device 2-1 according to the modification of the second example has a configuration that is similar to that of the light source device 2 according to the second example other than that the laser driver 5 includes the conductive bumps b1 and b2 as illustrated in FIG. 43.

### <13. Light Source Device According to Third Example of Second Embodiment>

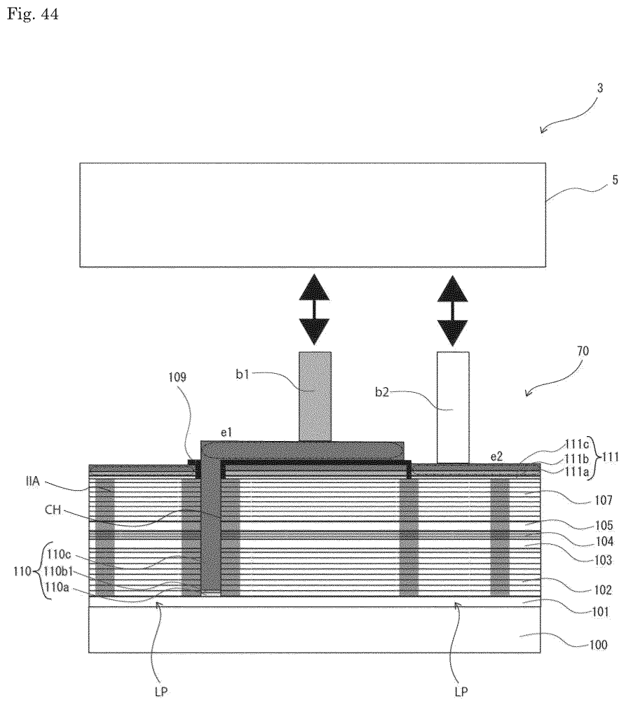

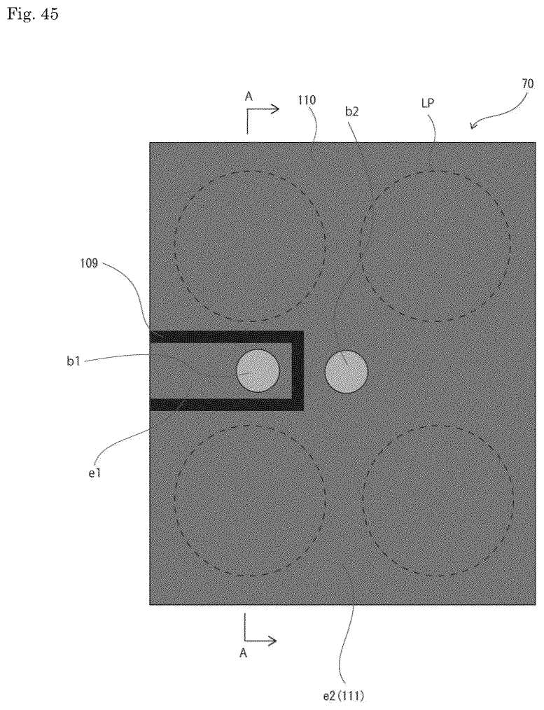

FIG. 44 is a sectional view illustrating a state before bonding of a light source device 3 according to a third example of the second embodiment of the present technology. FIG. 45 is a plan view of the surface emitting laser array 70 of the light source device 3 according to the third example of the second embodiment of the present technology.

The light source device 3 according to the third example includes the surface emitting laser array 70 and the laser driver 5 that is electrically connected to each of the first and second electrodes e1 and e2 of the surface emitting laser array 70 via a conductive bump as illustrated in FIGS. 44 and 45.

The surface emitting laser array 70 includes the conductive bumps b1 and b2 attached to the first and second electrodes e1 and e2, respectively.

Each conductive bump is, for example, a metal bump and is aligned in the in-plane direction.

The first electrode e1 is connected to a terminal of a laser driver on a side of a negative electrode via the conductive bump b1 in an example. The second electrode e2 is connected to a terminal of the laser driver on a side of a positive electrode via the conductive bump b2 in an example.

In the light source device 1, the surface emitting laser array 70 and the laser driver 5 are connected through flip-chip.

### <14. Light Source Device According to Modification of Third Example of Second Embodiment>

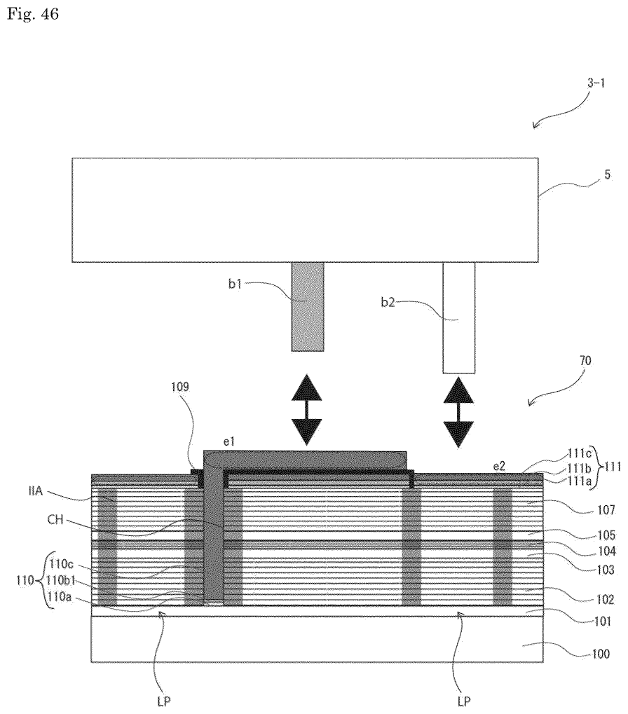

FIG. 46 is a sectional view illustrating a state before bonding of a light source device 3-1 according to a modification of the third example of the second embodiment of the present technology.

A light source device 3-1 according to the modification of the third example has a configuration that is similar to that of the light source device 3 according to the third example other than that the laser driver 5 includes the conductive bumps b1 and b2 as illustrated in FIG. 46.

### <15. Surface Emitting Laser According to Modification of Fourth Example of First Embodiment>

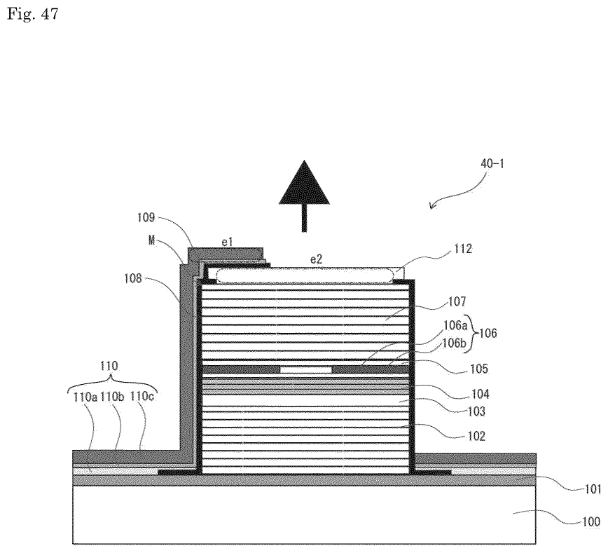

FIG. 47 is a sectional view of a surface emitting laser 40-1 according to a modification of the fourth example of the first embodiment.

The surface emitting laser 40-1 has a configuration that is substantially similar to that of the surface emitting laser 40 according to the fourth example other than that only the second electrode e2 is the transparent conductive film 112 and the oxidation constriction diameter of the oxidation constriction layer 106 is small.

Incidentally, the light emitting region of the active layer is small and a thin beam is generated as laser light in a surface emitting laser including an oxidation constriction layer with a small oxidation constriction diameter, and only the center portion of the top portion of the mesa M is needed to be transparent (specifically, transparent to an oscillation wavelength A).

Therefore, in a case where the wiring 110 is disposed at a position where the wiring 110 does not prevent laser light emission, it is not necessary that the material of the wiring 110 allow transmission of the laser light. Thus, the surface emitting laser 40-1 employs the configuration as described above.

### <16. Surface Emitting Laser Array According to First Modification of Seventh Example of First Embodiment>

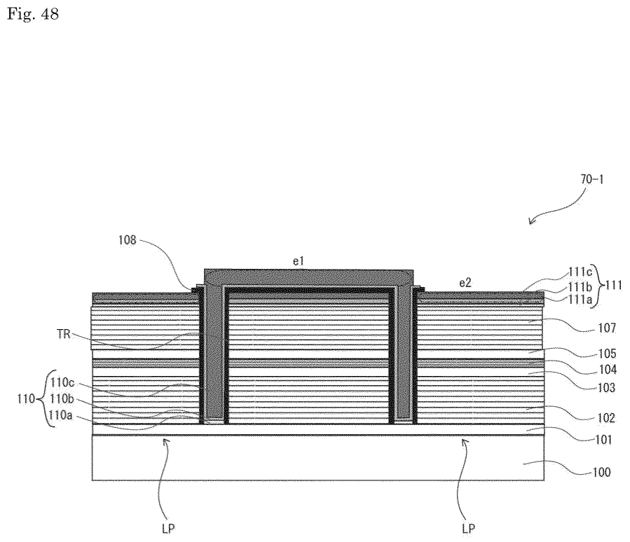

FIG. 48 is a sectional view of a surface emitting laser array 70-1 according to a first modification of the seventh example of the first embodiment.

The surface emitting laser array 70-1 has a configuration that is substantially similar to that of the surface emitting laser array 70 according to the seventh example other than that the insulating region surrounding the wiring 110 is the insulating film 108.

### <<Method for Manufacturing Surface Emitting Laser>>

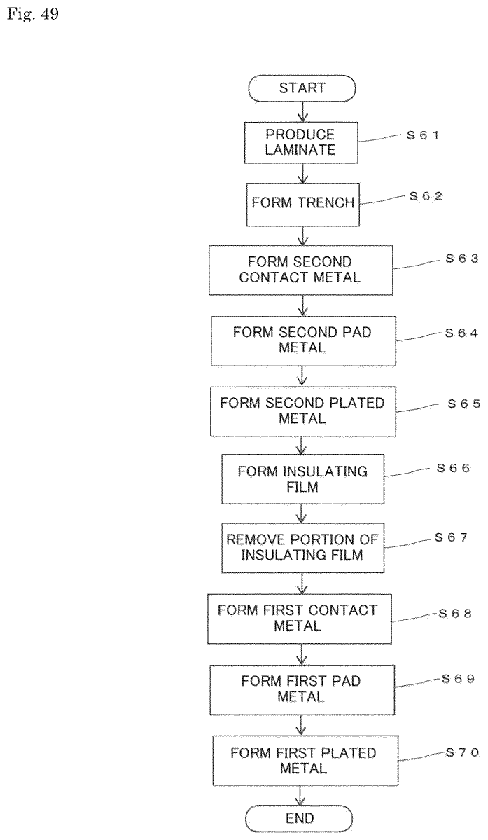

Hereinafter, a method for manufacturing the surface emitting laser array 70-1 will be described with reference to the flowchart (Step S61 to S70) in FIG. 49. Here, a plurality of surface emitting laser arrays 70-1 are simultaneously produced on a single wafer that is a base material of the substrate 100 by a semiconductor manufacturing method using a semiconductor manufacturing device in an example. Then, the series of plurality of integrated surface emitting laser arrays 70-1 are separated from each other to thereby obtain a plurality of surface emitting laser arrays 70-1 with a chip shape.

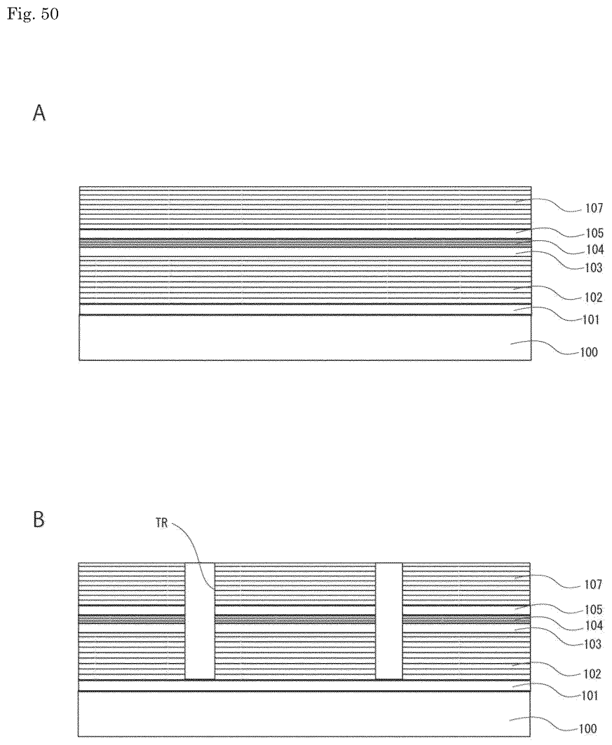

In first Step S61, a laminate is produced (see FIG. 50A). Here, the contact layer 101, the first multilayer reflector 102, the first cladding layer 103, the active layer 104, the second cladding layer 105, and the second multilayer reflector 107 are stacked (caused to experience epitaxial growth at a growth temperature of 605° C., for example) in this order on the substrate 100 in a growth chamber by the metal organic chemical vapor deposition (MOCVD) to thereby produce the laminate. Note that when the MOCVD is performed, trimethylgallium ((CH₃)₃Ga), for example, is used as raw material gas of gallium, trimethylaluminum ((CH₃)₃Al), for example, is used as raw material gas of aluminum, trimethylindium ((CH₃)₃In), for example, is used as raw material gas of indium, and trimethylarsine ((CH₃)₃As), for example, is used as raw material gas of As. Also, monosilane (SiH₄), for example, is used as raw material gas of silicon, and carbon tetrabromide (CBr₄), for example, is used as raw material gas of carbon.

In next Step S62, a trench TR (groove) is formed (see FIG. 50B). Specifically, locations of the laminate where the first contact metal 110a and the first pad metal 110b are to be provided are removed through etching (dry etching, for example) to thereby form the trench TR including the upper surface of the contact layer 101 as a bottom surface. The trench TR is formed into an annular shape in a plan view, for example.

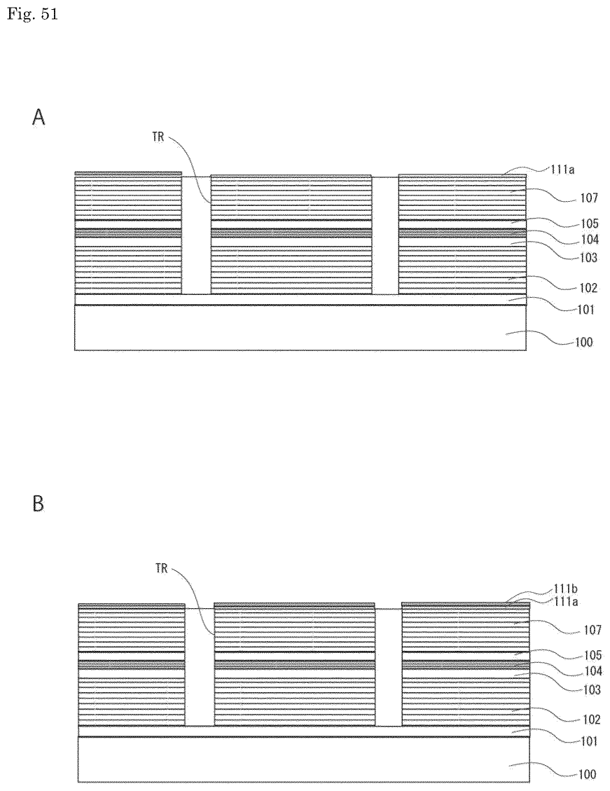

In next Step S63, the second contact metal 111a is formed (see FIG. 51A). Specifically, the second contact metal 111a is formed for each region where the light emitting portion LP is formed by the lift off method, for example, first.

In next Step S64, the second pad metal 111b is formed (see FIG. 51B). Specifically, the second pad metal 111b is formed on each second contact metal 111a on the lift-off method, for example.

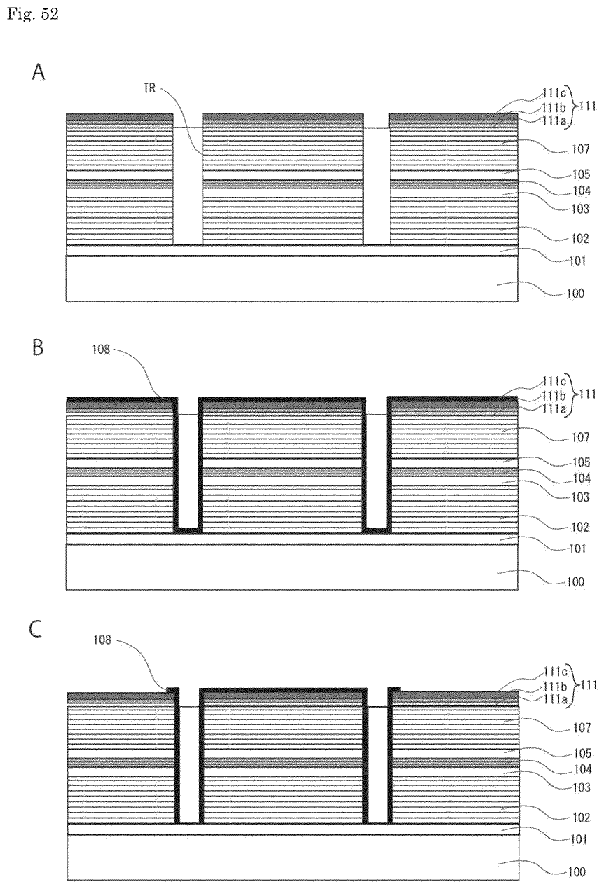

In next Step S65, the second plated metal 111c is formed (see FIG. 52A). Specifically, the second plated metal 111c is formed on each second pad metal 111b by the plating method, for example.

In next Step S66, the insulating film 108 is formed (see FIG. 52B). Specifically, the insulating film 108 is formed on the entire surface by the CVD method, the vacuum deposition method, or the sputtering method, for example.

In next Step S67, a portion of the insulating film 108 is removed (see FIG. 52C). Specifically, the insulating film 108 on the bottom surface of the trench TR and the insulating film 108 located at the position corresponding to each light emitting portion LP are removed by the RIE method with a solution containing hydrogen fluoride, for example. As a result, the contact layer 101 is exposed, and the stacked electrode 111 corresponding to each light emitting portion LP is exposed.

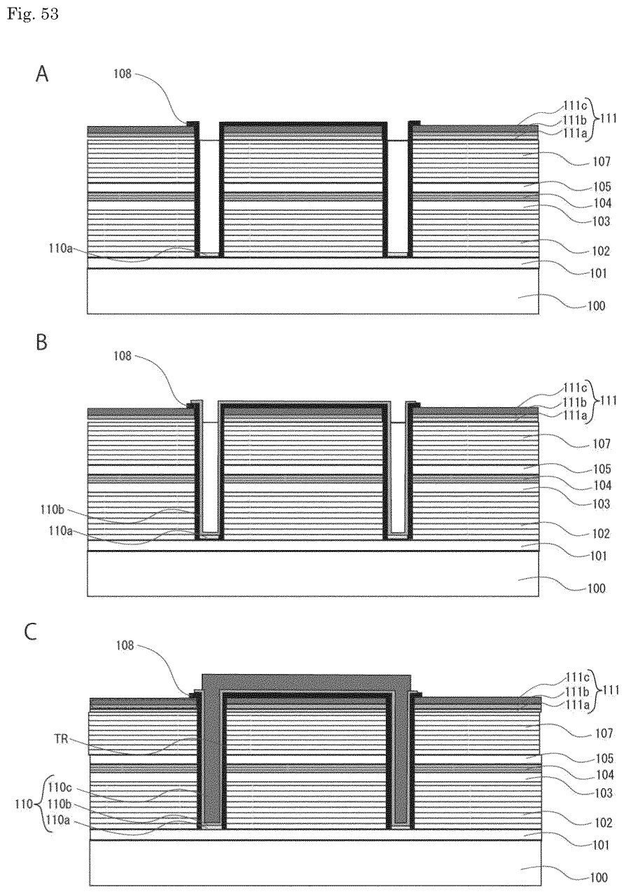

In next Step S68, the first contact metal 110a is formed (see FIG. 53A). Specifically, the first contact metal 110a is formed on the bottom surface of the trench TR (the upper surface of the contact layer 101) by the lift-off method, for example, first.

In next Step S69, the first pad metal 110b is formed (see FIG. 53B). Specifically, the first pad metal 110b is formed on the first contact metal 110a, on the inner surface of the trench TR, and on the insulating film 108 using the lift-off method, for example. The film formation of the first pad metal 110b is performed by the vacuum deposition method or the sputtering method, for example.

In last Step S70, the first plated metal 111c is formed (see FIG. 53C). Specifically, the first plated metal 110c is formed on the first pad metal 110b by the plating method, for example.

### <<Effects of Surface Emitting Laser>>

According to the surface emitting laser array 70-1 described above, it is possible to obtain effects that are similar to those of the surface emitting laser array 70 according to the seventh example.

### <17. Surface Emitting Laser According to Second Modification of Seventh Example of First Embodiment>

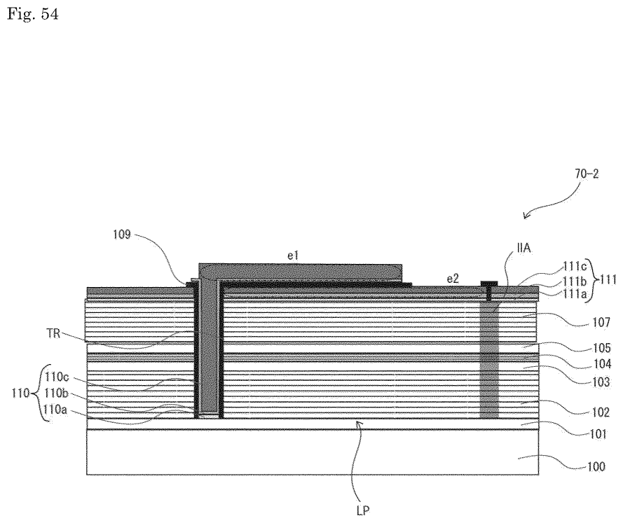

FIG. 54 is a sectional view of a surface emitting laser 70-2 according to a second modification of the seventh example of the first embodiment.

The surface emitting laser 70-2 has a configuration that is substantially similar to that of the surface emitting laser array 70-1 according to the first modification other than that the sizes of the light emitting portions LP are different.

In the surface emitting laser 70-2, one end of the light emitting portion LP in the in-plane direction is defined by the insulating film 108, and the other end is defined by the ion injection region IIA.

The system of the surface emitting laser array 70 according to the seventh example can emit light with a desired beam diameter by appropriately changing the section of the region serving as the light emitting portion LP as in the surface emitting laser 70-2, for example.

### <18. Surface Emitting Laser According to Third Modification of Seventh Example of First Embodiment>

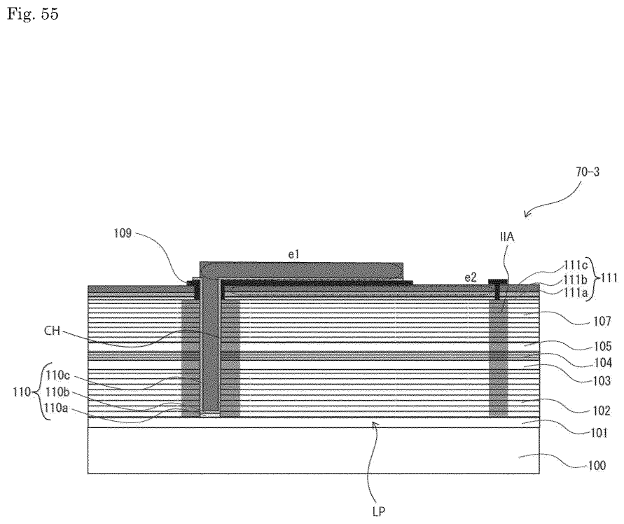

FIG. 55 is a sectional view of a surface emitting laser 70-3 according to a third modification of the seventh example of the first embodiment.

The surface emitting laser 70-3 has a configuration that is substantially similar to that of the surface emitting laser array 70 according to the seventh modification other than that the sizes of the light emitting portions LP are different.

In the surface emitting laser 70-3, both one end and the other end of the light emitting portion LP in the in-plane direction are defined by the ion injection region IIA.

The system of the surface emitting laser array 70 according to the seventh example can emit laser light with a desired beam diameter by appropriately changing the section of the region serving as the light emitting portion LP as in the surface emitting laser 70-3, for example.

### <19. Surface Emitting Laser According to Ninth Example of First Embodiment of Present Technology>

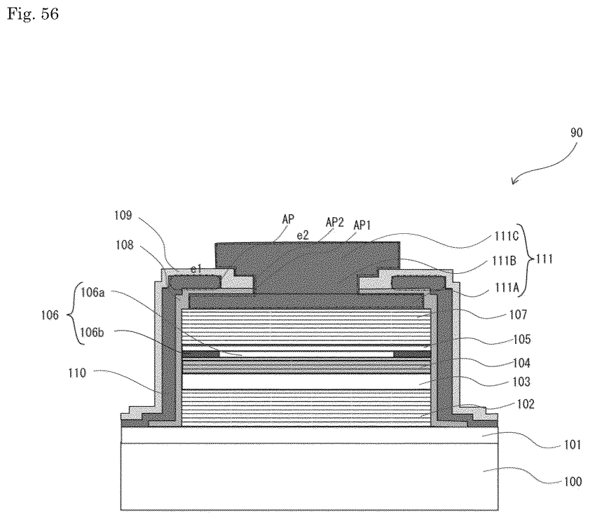

FIG. 56 is a sectional view of a surface emitting laser 90 according to a ninth example of the first embodiment of the present technology.

The surface emitting laser 90 has a configuration that is substantially similar to that of the surface emitting laser 10 according to the first example of the first embodiment other than that the first electrode e1 includes the opening portion AP, the insulating film 108 includes a first opening portion AP1 that is provided at a position corresponding to the opening portion AP and is smaller than the opening portion AP, and the first electrode e1 is covered with an insulating film 109 (different insulating film) including a second opening portion AP2 that is provided at a position corresponding to the opening portion AP and is smaller than the opening portion AP. Here, the first and second opening portions AP1 and AP2 have substantially the same size.

The opening portion AP is provided at a position in the first electrode e1 corresponding to the light emitting region of the active layer 104.

The second electrode e2 is provided to penetrate through the first and second opening portions AP1 and AP2. Specifically, the stacked electrode 111 serving as the second electrode e2 includes a first part 111A that is present between the surface of the second structure on the side opposite to the side of the active layer 104 (the upper surface of the second reflector 107, for example) and the insulating film 108, a second part 111B that is present inside the first and second opening portions AP1 and AP2, and a third part 111C that is present at least on the second part 111B. The first part 111A may be made of the contact metal 111a or may be made of the contact metal 111a and the pad metal 111b in an example. The second and third parts 111B and 111C may be made of the pad metal 111b, may be made of the pad metal 111b and the plated metal 111c, or may be made of the plated metal 111c in an example.

Although the third part 111C is also present on a region of the insulating film 109 in the surroundings of the second opening portion AP2 here, the third part 111C may not be present on the region.

In addition, the second and third parts 111B and 111C are not essential for the second electrode e2. In other words, the second electrode e2 may be configured by the first part 111A or may be configured by the first and second parts 111A and 111B.

The cathode electrode as the first electrode e1 is electrically connected to the negative electrode of the laser driver, and the anode electrode as the second electrode e2 is electrically connected to the positive electrode of the laser driver in the surface emitting laser 90 as well. The first electrode e1 may be electrically connected to the negative electrode of the laser driver in a direction that is perpendicular to the paper surface of FIG. 56, for example, or may be electrically connected to the negative electrode of the laser driver via a conductive bump, a part of which is provided inside the contact hole formed in the insulating film 109, for example.

According to the surface emitting laser 90, it is possible to obtain effects that are similar to those of the surface emitting laser 10 according to the first example of the first embodiment.

### <20. Surface Emitting Laser Array According to Tenth Example of First Embodiment of Present Technology>

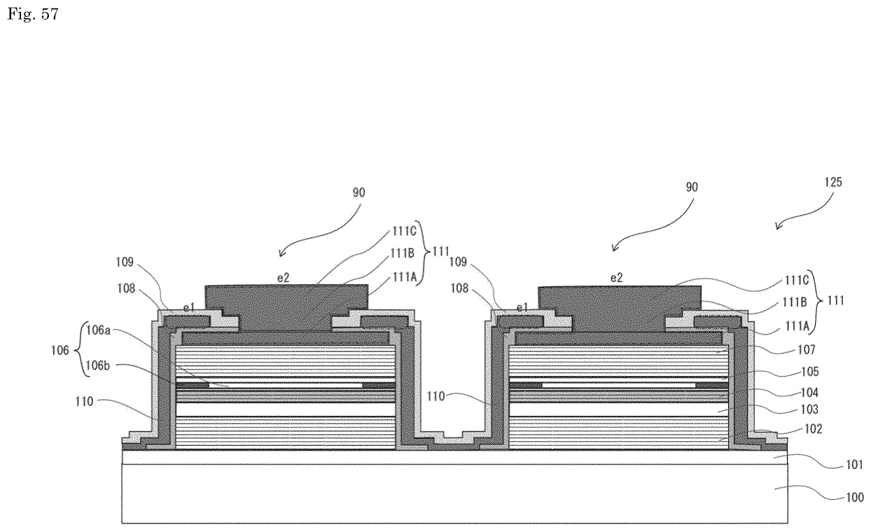

FIG. 57 is a sectional view of a surface emitting laser array 125 according to a tenth example of the first embodiment of the present technology.

The surface emitting laser array 125 includes a plurality of surface emitting lasers 90 according to the first example of the first embodiment, the first electrodes e1 of the plurality of surface emitting lasers 90 are electrically connected (the wirings 110 of the plurality of surface emitting lasers 90 are integrally provided), and the second electrodes e2 of the plurality of surface emitting lasers 90 are electrically separated. In other words, the surface emitting laser array 125 has a configuration in which the cathodes of the plurality of surface emitting lasers 90 are commonly used and the anodes are independently used, and it is possible to independently drive each surface emitting laser 90.

### <21. Other Modifications of Present Technology>

The present technology is not limited to each of the above examples and modifications and can be modified in various manners.

For example, the oxidation constriction layer may be provided at a part other than the second cladding layer 105 (the first cladding layer 103, the first multilayer reflector 102, or the second multilayer reflector 107, for example) in the surface emitting laser including the mesa M.

For example, current confinement in the surface emitting laser is not limited to that achieved by the oxidation constriction layer. For example, current confinement may be achieved through an increase in resistance achieved by ion injection, QWI in which a bandgap energy difference is provided inside and outside the aperture through Ga vacancy diffusion to confine the carrier, buried tunnel junction, for example.

For example, light confinement in the surface emitting laser is not limited to that achieved by the oxidation constriction layer. For example, a refractive index difference may be provided inside and outside the aperture such that the refractive index inside the aperture is higher by providing a stepped portion.

For example, the substrate 100 may be a GaN substrate, an InP substrate, or the like. In any cases, it is preferable to appropriately select a semiconductor layer to be stacked on the substrate 100 that lattice-matches the material of the substrate 100. It is also possible to use a material with any oscillation included in the wavelength band of 200 to 2000 nm for the surface emitting laser.

As the material for the first and second multilayer reflectors 102 and 107, at least one of a dielectric substance and metal may be contained, for example.

The wiring 110 and the stacked electrode 111 may not include all of the contact metal, the pad metal, and the plated metal. For example, the plated metal may not be included. Moreover, metal (such as Cu) of another material may be stacked on the plated metal.

The surface emitting laser array may be configured with surface emitting lasers with the mesas M disposed on an array.

A surface emitting laser with no mesa may include a plurality of first electrodes e1.

The first and second electrodes e1 and e2 may be disposed to be spaced apart from each other in both the stacked direction and the in-plane direction.

The contact layer may not necessarily be provided.

The shape of the light emitting portion in a plan view is not limited to the circular shape and may be a polygonal shape or an oval shape, for example.

The conductivity types (the n type and the p type) of the first and second structures in the surface emitting lasers in each of the above examples and modifications may be switched.

Portions of the configurations of the surface emitting lasers in the above examples and modifications may be combined within a range in which no conflict occurs therebetween.

The material, the conductivity type, the thickness, the width, the numerical value, and the like of each layer configuring the surface emitting laser may be appropriately changed within a range in which the function of the surface emitting laser is achieved in each of the examples and modifications described above.

### <22. Examples of Applications to Electronic Devices>

The technology according to the present disclosure (present technology) can be applied to a variety of products (electronic devices). For example, the technology according to the present disclosure may be implemented as a device to be mounted on a mobile object of any kind from an automobile, an electric vehicle, a hybrid electric vehicle, a motorcycle, a bicycle, a personal mobility, an aircraft, a drone, a ship, a robot, and the like, or a low-power-consumption device (such as a smartphone, a smart watch, a tablet, or a mouse, for example).

The surface emitting laser according to the present technology can also be applied as a light source for a device that forms or displays an image with laser light, for example (such as a laser printer, a laser copy machine, a projector, a head mount display, or a head-up display, for example).

<23. Example in which Surface Emitting Laser is Applied to Distance Measurement Device>

Hereinafter, an application example of the surface emitting laser according to each of the above embodiments and modifications will be described.

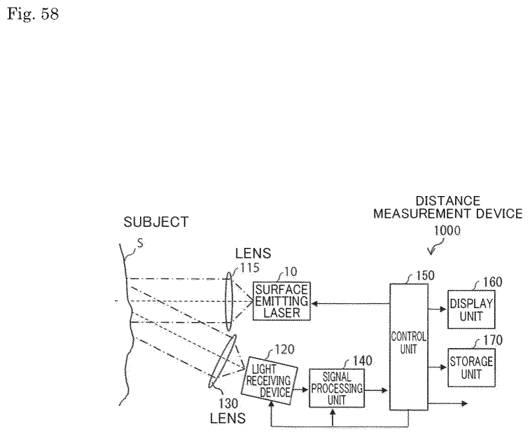

FIG. 58 represents an example of a schematic configuration of a distance measurement device 1000 including the surface emitting laser 10 as an example of an electronic device according to the present technology. The distance measurement device 1000 is adapted to measure the distance to the subject S by a time-of-flight (TOF) scheme. The distance measurement device 1000 includes the surface emitting laser 10 as a light source. The distance measurement device 1000 includes, for example, the surface emitting laser 10, a light receiving device 120, lenses 115 and 130, a signal processing unit 140, a control unit 150, a display unit 160, and a storage unit 170.

The light receiving device 120 detects light reflected by the subject S. The lens 115 is a lens for parallelizing light emitted from the surface emitting laser 10 and is a collimate lens. The lens 130 is a lens for collecting light reflected by the subject S and guiding the light to the light receiving device 120 and is a collecting lens.

The signal processing unit 140 is a circuit to generate a signal corresponding to a difference between a signal input from the light receiving device 120 and a reference signal input from the control unit 150. The control unit 150 is configured to include a time-to-digital converter (TDC), for example. The reference signal may be a signal input from the control unit 150 or may be an output signal of a detection unit that directly detects an output of the surface emitting laser 10. The control unit 150 is a processor that controls the surface emitting laser 10, the light receiving device 120, the signal processing unit 140, the display unit 160, and the storage unit 170, for example. The control unit 150 is a circuit that measures the distance to the subject S on the basis of the signal generated by the signal processing unit 140. The control unit 150 generates a video signal for displaying information regarding the distance to the subject S and outputs the video signal to the display unit 160. The display unit 160 displays the information regarding the distance to the subject S on the basis of the video signal input from the control unit 150. The control unit 150 stores the information regarding the distance to the subject S in the storage unit 170.

In the present application example, it is also possible to apply any of the above surface emitting lasers 20, 30, 40, 40-1, 50, 60, 70, 70-1, 70-2, 70-3, and 80 instead of the surface emitting laser 10 to the distance measurement device 1000.

<24. Example in which Distance Measurement Device is Mounted in Mobile Object>

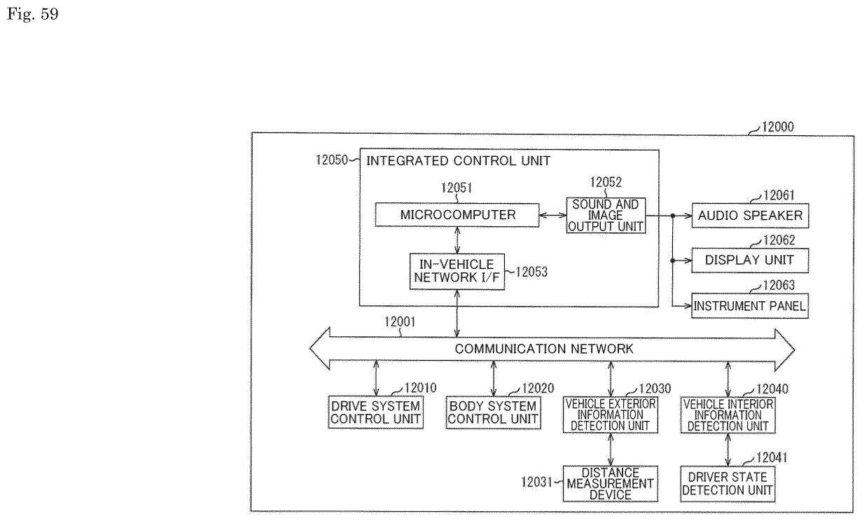

FIG. 59 is a block diagram illustrating a schematic configuration example of a vehicle control system, which is an example of a mobile object control system to which the technique according to the present disclosure can be applied.

The vehicle control system 12000 includes a plurality of electronic control units connected thereto via a communication network 12001. In the example illustrated in FIG. 59, the vehicle control system 12000 includes a drive system control unit 12010, a body system control unit 12020, a vehicle exterior information detection unit 12030, a vehicle interior information detection unit 12040, and an integrated control unit 12050. In addition, as a functional configuration of the integrated control unit 12050, a microcomputer 12051, a sound and image output unit 12052, and an in-vehicle network interface (I/F) 12053 are illustrated.

The drive system control unit 12010 controls an operation of an apparatus related to a drive system of a vehicle according to various programs. For example, the drive system control unit 12010 functions as a driving force generator for generating a driving force of a vehicle such as an internal combustion engine or a driving motor, a driving force transmission mechanism for transmitting a driving force to wheels, a steering mechanism for adjusting a turning angle of a vehicle, and a control apparatus such as a braking apparatus that generates a braking force of a vehicle.

The body system control unit 12020 controls operations of various devices mounted in the vehicle body according to various programs. For example, the body system control unit 12020 functions as a control device of a keyless entry system, a smart key system, a power window device, or various lamps such as a headlamp, a back lamp, a brake lamp, a turn signal, and a fog lamp. In this case, radio waves transmitted from a portable device that substitutes for a key or signals of various switches may be input to the body system control unit 12020. The body system control unit 12020 receives inputs of the radio waves or signals and controls a door lock device, a power window device, and a lamp of the vehicle.

A vehicle exterior information detection unit 12030 detects information outside a vehicle in which the vehicle control system 12000 is mounted. For example, a distance measurement device 12031 is connected to the vehicle exterior information detection unit 12030. The distance measurement device 12031 includes the aforementioned distance measurement device 1000. The vehicle exterior information detection unit 12030 causes the distance measurement device 12031 to measure the distance to an object (subject S) outside the vehicle and acquires the thus obtained distance data. The vehicle exterior information detection unit 12030 may perform processing of detecting an object such as a person, a vehicle, an obstacle, or a sign on the basis of the acquired distance data.

The vehicle interior information detection unit 12040 detects information on the inside of the vehicle. For example, a driver state detection unit 12041 that detects a driver's state is connected to the vehicle interior information detection unit 12040. The driver state detection unit 12041 includes, for example, a camera that captures an image of a driver, and the vehicle interior information detection unit 12040 may calculate a degree of fatigue or concentration of the driver or may determine whether or not the driver is dozing on the basis of detection information input from the driver state detection unit 12041.

The microcomputer 12051 can calculate a control target value of the driving force generation device, the steering mechanism, or the braking device on the basis of information inside and outside of the vehicle acquired by the vehicle exterior information detection unit 12030 or the vehicle interior information detection unit 12040, and output a control command to the drive system control unit 12010. For example, the microcomputer 12051 can perform cooperative control for the purpose of realizing functions of an ADAS (advanced driver assistance system) including vehicle collision avoidance, impact mitigation, following traveling based on an inter-vehicle distance, vehicle speed maintenance driving, vehicle collision warning, vehicle lane deviation warning, and the like.

Further, the microcomputer 12051 can perform cooperative control for the purpose of automated driving or the like in which autonomous travel is performed without depending on operations of the driver, by controlling the driving force generator, the steering mechanism, or the braking device and the like on the basis of information about the surroundings of the vehicle, the information being acquired by the vehicle exterior information detection unit 12030 or the vehicle interior information detection unit 12040.

In addition, the microcomputer 12051 can output a control command to the body system control unit 12020 based on the information acquired by the vehicle exterior information detection unit 12030 outside the vehicle. For example, the microcomputer 12051 can perform cooperative control for the purpose of preventing glare, such as switching from a high beam to a low beam, by controlling the headlamp according to the position of a preceding vehicle or an oncoming vehicle detected by the vehicle exterior information detection unit 12030.

The sound and image output unit 12052 transmits an output signal of at least one of sound and an image to an output device capable of visually or audibly notifying a passenger or the outside of the vehicle of information. In the example of FIG. 59, an audio speaker 12061, a display unit 12062, and an instrument panel 12063 are illustrated as examples of the output device. The display unit 12062 may include at least one of an on-board display and a head-up display, for example.

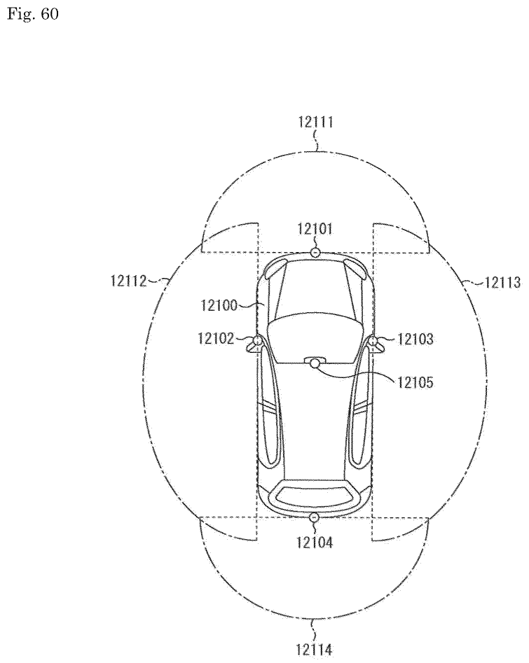

FIG. 60 is a diagram illustrating an example of an installation position of the distance measurement device 12031.

In FIG. 60, the vehicle 12100 includes, as distance measurement devices 12031, distance measurement devices 12101, 12102, 12103, 12104, and 12105.

The distance measurement devices 12101, 12102, 12103, 12104, and 12105 are provided at positions such as a front nose, side view mirrors, a rear bumper, and upper portions of the rear door and the front glass in the interior of the vehicle 12100, for example. The distance measurement device 12101 provided on the front nose and the distance measurement device 12105 provided at the upper portion of the front glass inside the vehicle mainly acquire data in front of the vehicle 12100. The distance measurement devices 12102 and 12103 included in the side view mirrors mainly acquire data on the lateral side of the vehicle 12100. The distance measurement device 12104 included in the rear bumper or the rear door mainly acquires data behind the vehicle 12100. The data on the front side acquired by the distance measurement devices 12101 and 12105 is used to detect mainly a preceding vehicle, a pedestrian, an obstacle, a traffic light, a traffic sign, or the like.

Note that FIG. 60 illustrates an example of detection ranges of the distance measurement devices 12101 to 12104. A detection range 12111 indicates a detection range of the distance measurement device 12101 provided at the front nose, detection ranges 12112 and 12113 indicate detection ranges of the distance measurement devices 12102 and 12103 provided at the side view mirrors, respectively, and the detection range 12114 denotes a detection range of the distance measurement device 12104 provided at the rear bumper or the rear door.

For example, the microcomputer 12051 can extract, particularly, a closest three-dimensional object on a path through which the vehicle 12100 is traveling, which is a three-dimensional object traveling at a predetermined speed (for example, 0 km/h or higher) in the substantially same direction as the vehicle 12100, as a vehicle ahead by obtaining a distance to each three-dimensional object in the detection ranges 12111 to 12114 and temporal change in the distance (a relative speed with respect to the vehicle 12100) based on distance data obtained from the distance measurement devices 12101 to 12104. The microcomputer 12051 can also set a following distance to the vehicle ahead to be maintained in advance and perform automatic brake control (including following stop control) and automatic acceleration control (including following start control). Thus, it is possible to perform cooperative control for the purpose of, for example, automated driving in which the vehicle travels in an automated manner without requiring the driver to perform operations.

For example, the microcomputer 12051 can classify and extract three-dimensional data regarding three-dimensional objects into two-wheeled vehicles, normal vehicles, large vehicles, pedestrians, and other three-dimensional objects such as electric poles based on distance data obtained from the distance measurement devices 12101 to 12104 and can use the three-dimensional data to perform automated avoidance of obstacles. For example, the microcomputer 12051 identifies obstacles in the vicinity of the vehicle 12100 into obstacles that can be visually recognized by the driver of the vehicle 12100 and obstacles that are difficult to be visually recognized by the driver. Then, the microcomputer 12051 can determine a risk of collision indicating the degree of risk of collision with each obstacle and can perform driving assistance for collision avoidance by outputting a warning to the driver through the audio speaker 12061 or the display unit 12062 and performing forced deceleration or avoidance steering through the drive system control unit 12010 when the risk of collision has a value equal to or greater than a set value and there is a possibility of collision.

An example of the mobile object control system to which the technology according to the present disclosure can be applied has been described above. The technology according to the present disclosure can be applied to the distance measurement device 12031 among the configurations described above.

Specific numerical values, shapes, materials (including compositions), and the like described in the specification are examples, and the present technology is not limited thereto.

In addition, the present technology can also have the following configurations.

(1) A surface emitting laser including:
a first structure that includes a first multilayer reflector;
a second structure that includes a second multilayer reflector;
an active layer that is disposed between the first and second structures;
a first electrode that is electrically connected to the first structure; and
a second electrode that is electrically connected to the second structure, in which
the first and second electrodes are provided in the second structure in a state in which the first and second electrodes are insulated from each other.
   (2) The surface emitting laser according to (1), in which the first and second electrodes are disposed on the second structure on a side opposite to a side of the active layer.
   (3) The surface emitting laser according to (1) or (2), in which the first and second electrodes are disposed to be aligned in at least one of a stacked direction and an in-plane direction.
   (4) The surface emitting laser according to any one of (1) to (3), in which the second electrode is provided on a surface of the second structure on a side opposite to a side of the active layer.
   (5) The surface emitting laser according to any one of (1) to (4), in which the first and second electrodes are stacked via an insulating film.
   (6) The surface emitting laser according to any one of (1) to (5), in which the first electrode is provided on the surface via an insulating film.
   (7) The surface emitting laser according to any one of (1) to (6), in which the first electrode is smaller than the second electrode.
   (8) The surface emitting laser according to any one of (1) to (7), in which one of the first and second electrodes surrounds the other in a plan view.
   (9) The surface emitting laser according to any one of (1) to (8), in which the first electrode is another portion of a wiring, a portion of which is connected to the first structure.
   (10) The surface emitting laser according to (9), in which a mesa having a top portion in the second structure is configured by at least the second structure and the active layer from among a portion of the first structure, the second structure, and the active layer, and the wiring is provided along the mesa via an insulating film.
   (11) The surface emitting laser according to (10), in which the portion of the wiring is in contact with a surface of the first structure exposed in surroundings of the mesa.
   (12) The surface emitting laser according to (10) or (11), in which the first structure further includes a substrate that is disposed on a side opposite to a side of the active layer with respect to the first multilayer reflector and a contact layer that is disposed between the substrate and the active layer and is exposed in surroundings of the mesa, and the portion of the wiring is in contact with the contact layer.
   (13) The surface emitting laser according to (10) or (11), in which the first structure further includes a cladding layer that is disposed on the first multilayer reflector on a side of the active layer and is exposed in surroundings of the mesa, and the portion of the wiring is in contact with the cladding layer.
   (14) The surface emitting laser according to any one of (10) to (13), in which a plurality of the first electrodes are provided.
   (15) The surface emitting laser according to (9), in which the wiring is provided to penetrate through at least the second structure and the active layer from among the first structure, the second structure, and the active layer and is surrounded by an insulating region provided across at least the second structure and the active layer from among the first structure, the second structure, and the active layer.
   (16) The surface emitting laser according to (15), in which the first structure further includes a substrate that is disposed on a side opposite to a side of the active layer with respect to the first multilayer reflector and a contact layer that is disposed between the substrate and the active layer, and the portion of the wiring is in contact with the contact layer.
   (17) The surface emitting laser according to any one of (1) to (16), in which at least the second electrode out of the first and second electrodes is made of a transparent conductive film.
   (18) A surface emitting laser array comprising:
a plurality of the surface emitting lasers according to any one of (1) to (17).
   (19) The surface emitting laser according to (18), in which the first electrode and/or the second electrode are provided commonly in least two of the surface emitting lasers.
   (20) A laser driver comprising:
the surface emitting laser according to any one of (1) to (17); and
a laser driver that is electrically connected to each of the first and second electrodes of the surface emitting lasers via a conductive bump.
   (21) The surface emitting laser according to any one of (5) to (17), in which the first electrode includes an opening portion, the insulating film includes a first opening portion that is provided at a position corresponding to the opening portion and is smaller than the opening portion, and the first electrode is covered with a different insulating film including a second opening portion that is provided at a position corresponding to the opening portion and is smaller than the opening portion.
   (22) The surface emitting laser according to (21), in which the second electrode is provided to penetrate through the first and second opening portions.
   (23) The surface emitting laser according to (21) or (22), in which the second electrode includes a first part that is present between the surface and the insulating film, a second part that is present inside the first and second opening portions, and a third part that is present at least on the second part.
   (24) The surface emitting laser according to (23), in which the third part is also present on a region in surroundings of the second opening portion in the different insulating film.
   (25) A surface emitting laser array including: a plurality of the surface emitting lasers according to any one of (21) to (24), in which the first electrodes of the plurality of surface emitting lasers are electrically connected.

### REFERENCE SIGNS LIST

1, 1-1, 2, 2-1, 3, 3-1 Light source device
5 Laser driver
10, 20, 30, 40, 40-1, 50, 60, 70, 70-1, 70-2, 70-3, 80 Surface emitting laser
100 Substrate
101 Contact layer
102 First multilayer reflector
103 First cladding layer
104 Active layer
105 Second cladding layer
106 Oxidation constriction layer
107 Second multilayer reflector
108 Insulating film
109 Insulating film (different film)
110 Wiring
111 Stacked electrode
S1 First structure
S2 Second structure
M Mesa
e1 First electrode
e2 Second electrode
b1, b2 Conductive bump
AP Opening portion
AP1 First opening portion
AP2 Second opening portion
111A First part
111B Second part
111C Third part
1000 Distance measurement device (electronic device)

1. A surface emitting laser comprising:
a first structure that includes a first multilayer reflector;
a second structure that includes a second multilayer reflector;
an active layer that is disposed between the first and second structures;
a first electrode that is electrically connected to the first structure; and
a second electrode that is electrically connected to the second structure, wherein
the first and second electrodes are provided in the second structure in a state where the first and second electrodes are insulated from each other.

2. The surface emitting laser according to claim 1, wherein the first and second electrodes are disposed on the second structure on a side opposite to a side of the active layer.

3. The surface emitting laser according to claim 2, wherein the first and second electrodes are disposed to be aligned in at least one of a stacked direction and an in-plane direction.

4. The surface emitting laser according to claim 2, wherein the second electrode is provided on a surface of the second structure on the side opposite to the side of the active layer.

5. The surface emitting laser according to claim 4, wherein the first and second electrodes are stacked via an insulating film.

6. The surface emitting laser according to claim 4, wherein the first electrode is provided on the surface via an insulating film.

7. The surface emitting laser according to claim 5, wherein the first electrode is smaller than the second electrode.

8. The surface emitting laser according to claim 2, wherein one of the first and second electrodes surrounds the other in a plan view.

9. The surface emitting laser according to claim 1, wherein the first electrode is another portion of a wiring, a portion of which is connected to the first structure.

10. The surface emitting laser according to claim 9,
wherein a mesa having a top portion in the second structure is configured by at least the second structure and the active layer from among a portion of the first structure, the second structure, and the active layer, and the wiring is provided along the mesa via an insulating film.

11. The surface emitting laser according to claim 10, wherein the portion of the wiring is in contact with a surface of the first structure exposed in surroundings of the mesa.

12. The surface emitting laser according to claim 11,
wherein the first structure further includes
a substrate that is disposed on a side opposite to a side of the active layer with respect to the first multilayer reflector, and
a contact layer that is disposed between the substrate and the active layer and is exposed in surroundings of the mesa, and
the portion of the wiring is in contact with the contact layer.

13. The surface emitting laser according to claim 11,
wherein the first structure further includes a cladding layer that is disposed on the first multilayer reflector on a side of the active layer and is exposed in the surroundings of the mesa, and the portion of the wiring is in contact with the cladding layer.

14. The surface emitting laser according to claim 2, wherein a plurality of the first electrodes are provided.

15. The surface emitting laser according to claim 9, wherein the wiring is provided to penetrate through at least the second structure and the active layer from among the first structure, the second structure, and the active layer, and is surrounded by an insulating region provided across at least the second structure and the active layer from among the first structure, the second structure, and the active layer.

16. The surface emitting laser according to claim 15,
wherein the first structure further includes
a substrate that is disposed on a side opposite to a side of the active layer with respect to the first multilayer reflector, and
a contact layer that is disposed between the substrate and the active layer, and
the portion of the wiring is in contact with the contact layer.

17. The surface emitting laser according to claim 1, wherein at least the second electrode out of the first and second electrodes is made of a transparent conductive film.

18. A surface emitting laser array comprising a plurality of the surface emitting lasers according to claim 1.

19. The surface emitting laser array according to claim 18, wherein the first electrode and/or the second electrode is provided commonly in at least two of the surface emitting lasers.

20. A light source device comprising:
the surface emitting laser according to claim 1; and
a laser driver that is electrically connected to each of the first and second electrodes of the surface emitting laser via a conductive bump.

21. The surface emitting laser according to claim 5,
wherein the first electrode includes an opening portion, the insulating film has a first opening portion that is provided at a position corresponding to the opening portion and is smaller than the opening portion, and
the first electrode is covered with a different insulating film including a second opening portion that is provided at a position corresponding to the opening portion and is smaller than the opening portion.

22. The surface emitting laser according to claim 21, wherein the second electrode is provided to penetrate through the first and second opening portions.

23. The surface emitting laser according to claim 21,
wherein the second electrode includes
a first part that is present between the surface and the insulating film,
a second part that is present inside the first and second opening portions, and
a third part that is present at least on the second part.

24. The surface emitting laser according to claim 23, wherein the third part is also present on a region in surroundings of the second opening portion in the different insulating film.

25. A surface emitting laser array comprising:
a plurality of the surface emitting lasers according to claim 21,
wherein the first electrodes of the plurality of surface emitting lasers are electrically connected.
